(19) United States
(12) Patent Application Publication
(10) Pub. No.: US 2025/0081776 A1
(43) Pub. Date: Mar. 6, 2025

(54) DISPLAY DEVICE AND MOBILE ELECTRONIC DEVICE INCLUDING THE SAME

(71) Applicant: Samsung Display Co., LTD., Yongin-si (KR)

(72) Inventors: Kyeong Min PARK, Yongin-si (KR); Yong Hee LEE, Yongin-si (KR); Kyung Bae KIM, Yongin-si (KR); Jong Woong CHANG, Yongin-si (KR)

(21) Appl. No.: 18/741,107

(22) Filed: Jun. 12, 2024

(30) Foreign Application Priority Data
Sep. 4, 2023 (KR) 10-2023-0117137

(51) Int. Cl. H10K 59/131; H10K 59/122

(52) U.S. Cl. CPC H10K 59/131; H10K 59/122

(57) ABSTRACT

A display device and a mobile electronic device including the same are provided. The display device includes: a pixel defining layer; a first electrode located in an opening of the pixel defining layer; a wiring including: a first wiring extending in a first direction, and having a first length in a display area; and a second wiring having a second length shorter than the first length; an intermediate layer covering the first electrode at the opening, a portion of the intermediate layer being disconnected in an upper portion of the wiring; a second electrode covering the intermediate layer in the opening; and pattern wirings connected to the wirings in a non-display area and including a third wiring connected to the first wiring and having a third length, and a fourth wiring connected to the second wiring and having a fourth length longer than the third length.

### CROSS-REFERENCE TO RELATED APPLICATION

The present application claims priority to and the benefit of Korean Patent Application No. 10-2023-0117137, filed on Sep. 4, 2023, in the Korean Intellectual Property Office, the entire content of which is incorporated by reference herein.

### BACKGROUND

### 1. Field

Aspects of embodiments of the present disclosure relate to a display device, and a mobile electronic device including the display device.

### 2. Description of the Related Art

A wearable device developed in the form of glasses or a helmet to focus on a distance close to the user's eyes is being developed. For example, the wearable device may be a head mounted display (HMD) device or augmented reality (AR) glasses. Such a wearable device provides a user with an augmented reality screen, or a virtual reality (VR) screen.

The wearable device developed in the form of the HMD device or the AR glasses may use a display specification of at least 2000 pixels per inch (PPI) to allow the user to use the device for a long time without feeling dizzy. As such, organic light emitting diode on silicon (OLEDoS) technology, which is a small organic light emitting display device with a high resolution, is emerging. OLEDoS is a technology that disposes organic light emitting diodes (OLEDs) on a semiconductor wafer substrate on which a complementary metal oxide semiconductor (CMOS) is disposed.

The above information disclosed in this Background section is for enhancement of understanding of the background of the present disclosure, and therefore, it may contain information that does not constitute prior art.

### SUMMARY

As a spacing between pixels in a display panel to which the OLEDoS technology is applied narrows, an unintended leakage current may occur between adjacent pixels. The leakage current may occur through some conductive layers from among the intermediate layers disposed between a pixel electrode (e.g., an anode electrode) and a common electrode (e.g., a cathode electrode), and may cause color crosstalk between the adjacent pixels.

One or more embodiments of the present disclosure may be directed to a display device capable of preventing or substantially preventing a leakage current and/or a color crosstalk phenomenon, by disconnecting at least a portion of an intermediate layer disposed between a pixel electrode and a common electrode between adjacent pixels using wirings, and a mobile electronic device including the display device.

One or more embodiments of the present disclosure may be directed to a display device including a disconnection portion of an intermediate layer (e.g., where the intermediate layer is disconnected) having a uniform or substantially uniform width and height, and capable of reducing product defects due to process deviations of the disconnection portion, by compensating for a resistance deviation or variation due to a length deviation or variation of wirings, and a mobile electronic device including the display device.

According to one or more embodiments of the present disclosure, a display device includes: a substrate; a driving element layer on the substrate; and a light emitting element layer on the driving element layer, the light emitting element layer including: a pixel defining layer partitioning a plurality of sub-pixels; a first electrode of a sub-pixel from among the plurality of sub-pixels, the first electrode being located in an opening of the pixel defining layer; wirings including: a first wiring extending in a first direction while crossing between the first electrodes on the pixel defining layer, and having a first length in a display area; and a second wiring having a second length shorter than the first length in the display area; an intermediate layer covering the first electrode at the opening and covering the pixel defining layer, a portion of the intermediate layer being disconnected in an upper portion of the wirings; a second electrode covering the intermediate layer in the opening, and continuously covering the intermediate layer and the wirings between sub-pixels that are adjacent to each other from among the plurality of sub-pixels; and pattern wirings connected to the wirings in a non-display area and including a third wiring and a fourth wiring. The third wiring is connected to the first wiring and has a third length, and the fourth wiring is connected to the second wiring and has a fourth length longer than the third length.

In an embodiment, the fourth wiring may have a zigzag shape to have the fourth length longer than the third length.

In an embodiment, a first total length obtained by adding the first length of the first wiring and the third length of the third wiring to each other may be equal to a second total length obtained by adding the second length of the second wiring and the fourth length of the fourth wiring to each other.

In an embodiment, the first wiring may be an odd-numbered wiring of the wirings, and the second wiring may be an even-numbered wiring of the wirings.

In an embodiment, the power pad may be located at one end of the non-display area adjacent to one end of the wirings, and another end of the non-display area adjacent to another end of the wirings may include a first ground wiring and a second ground wiring connecting a ground pad and the wirings to each other. The first ground wiring may be connected to the first wiring and may extend in a straight line. The second ground wiring may be connected to the second wiring and may have a zigzag shape.

In an embodiment, the ground pad may be located at the other end of the non-display area.

In an embodiment, the first electrode may have a hexagonal shape in a plan view, and may include a protruding portion protruding in a direction of the first wiring.

In an embodiment, the plurality of sub-pixels may include: a first light emitting area of a first sub-pixel; a second light emitting area of a second sub-pixel; and a third light emitting area of a third sub-pixel. The first light emitting area and the second light emitting area may be alternately located along the first direction in odd-numbered rows from among the plurality of sub-pixels, and the third light emitting area may be located at intervals along the first direction in even-numbered rows from among the plurality of sub-pixels. A length of the third light emitting area in the first direction may be greater than a sum of a length of the first light emitting area in the first direction and a length of the second light emitting area in the first direction.

In an embodiment, the first wiring may include: a first portion between a first light emitting area and a third light emitting area; a second portion extending from the first portion, and located between the first light emitting area and a second light emitting area; and a third portion extending from the second portion, and located between the second light emitting area and the third light emitting area. The second wiring may include: a fourth portion between the third light emitting area and the first and second light emitting areas; and a fifth portion between two third light emitting areas adjacent to each other.

In an embodiment, the display device may further include a plurality of fan-out wirings connecting between the pattern wirings and the power pad. The plurality of fan-out wirings may all have the same length as each other by including a length deviation compensation portion, and the length deviation compensation portion of each of the fan-out wirings may include a zigzag wiring of a different length from those of others of the fan-out wirings.

According to one or more embodiments of the present disclosure, a mobile electronic device includes: a display panel including a light emitting element layer. The light emitting element layer includes: a pixel defining layer partitioning a plurality of sub-pixels; a first electrode of a sub-pixel from among the plurality of sub-pixels, the first electrode being located in an opening of the pixel defining layer; a wiring including: a first wiring extending in a first direction while crossing between the first electrodes on the pixel defining layer, and having a first length in a display area; and a second wiring having a second length shorter than the first length in the display area; an intermediate layer covering the first electrode at the opening and covering the pixel defining layer, a portion of the intermediate layer being disconnected in an upper portion of the wirings; a second electrode covering the intermediate layer in the opening, and continuously covering the intermediate layer and the wirings between sub-pixels that are disposed to be adjacent to each other from among the plurality of sub-pixels; and pattern wirings connected to the wirings in a non-display area and including a third wiring and a fourth wiring. The third wiring is connected to the first wiring and has a third length. The fourth wiring is connected to the second wiring, and has a fourth length longer than the third length.

In an embodiment, the fourth wiring may have a zigzag shape to have the fourth length longer than the third length.

In an embodiment, a first total length obtained by adding the first length of the first wiring and the third length of the third wiring to each other may be equal to a second total length obtained by adding the second length of the second wiring and the fourth length of the fourth wiring to each other.

In an embodiment, the first wiring may be an odd-numbered wiring of the wirings, and the second wiring may be an even-numbered wiring of the wirings.

In an embodiment, the power pad may be located at one end of the non-display area adjacent to one end of the wirings, and another end of the non-display area adjacent to another end of the wirings may include a first ground wiring and a second ground wiring connecting a ground pad and the wirings to each other. The first ground wiring may be connected to the first wiring and may extend in a straight line, and the second ground wiring may be connected to the second wiring and may have a zigzag shape.

In an embodiment, the ground pad may be located at the other end of the non-display area.

In an embodiment, the first electrode may have a hexagonal shape in a plan view, and may include a protruding portion protruding in a direction of the first wiring.

In an embodiment, the plurality of sub-pixels may include: a first light emitting area of a first sub-pixel; a second light emitting area of a second sub-pixel; and a third light emitting area of a third sub-pixel. The first light emitting area and the second light emitting area may be alternately located along the first direction in odd-numbered rows from among the plurality of sub-pixels. The third light emitting area may be located at intervals along the first direction in even-numbered rows from among the plurality of sub-pixels. A length of the third light emitting area in the first direction may be greater than a sum of a length of the first light emitting area in the first direction and a length of the second light emitting area in the first direction.

In an embodiment, the first wiring may include: a first portion between a first light emitting area and a third light emitting area; a second portion extending from the first portion, and located between the first light emitting area and a second light emitting area; and a third portion extending from the second portion, and located between the second light emitting area and the third light emitting area. The second wiring may include: a fourth portion between the third light emitting area and the first and second light emitting areas; and a fifth portion between two third light emitting areas adjacent to each other.

In an embodiment, the mobile electronic device may further include a plurality of fan-out wirings connecting between the pattern wirings and the power pad. The plurality of fan-out wirings may all have the same length as each other by including a length deviation compensation portion, and the length deviation compensation portion of each of the fan-out wirings may include a zigzag wiring of a different length from those of others of the fan-out wirings.

According to one or more embodiments of the present disclosure, a leakage current and a color crosstalk phenomenon in a display device and a mobile device including the same may be prevented or substantially prevented by disconnecting at least a portion of the intermediate layer disposed between the pixel electrode and the common electrode between adjacent pixels using the wirings.

According to one or more embodiments of the present disclosure, the width and the height of the disconnection portion of the intermediate layer (e.g., where the intermediate layer is disconnected) may be uniformalized (e.g., may be uniformly or substantially uniformly formed), and product defects due to a process deviation or variation of the disconnection portion may be reduced, by compensating for a resistance deviation or variation due to the length deviation or variation of the wirings.

However, the aspects and features of the present disclosure are not restricted to those described above. The above and other aspects and features of the present disclosure will become more apparent to those having ordinary skill in the art from the detailed description of the present disclosure below with reference to the drawings, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view illustrating a head mounted display device according to an embodiment;

FIG. 2 is an exploded perspective view of the head mounted display device of FIG. 1;

FIG. 3 is a perspective view illustrating a head mounted display device according to an embodiment;

FIG. 4 is an exploded perspective view illustrating a display device according to an embodiment;

FIG. 5 is a layout view illustrating a display panel of FIG. 4;

FIG. 6 is a block diagram illustrating a display device according to an embodiment;

FIG. 7 is an equivalent circuit diagram of a first sub-pixel according to an embodiment;

FIG. 8 is a layout view illustrating pixels of a display area according to an embodiment;

FIG. 9 is a cross-sectional view illustrating an example in which a portion of a display panel is cut according to an embodiment;

FIG. 10 is a plan view illustrating an arrangement of first electrodes of sub-pixels according to an embodiment;

FIG. 11 is a cross-sectional view schematically illustrating a connection between a reference wiring and a pad portion of a display panel according to an embodiment;

FIG. 12 is a layout view illustrating a pad portion and fan-out lines disposed in a non-display area of a display panel according to an embodiment;

FIG. 13 is an enlarged view illustrating more details of wirings between a power pad and a reference wiring illustrated in FIG. 12;

FIG. 14 is a flowchart illustrating a method of manufacturing a display device according to an embodiment; and

FIGS. 15-18 are cross-sectional views illustrating various processes of a method of manufacturing a display device.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below”, “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the X-axis, the Y-axis, and the Z-axis are not limited to three axes of the rectangular coordinate system, and may be interpreted in a broader sense. For example, the X-axis, the Y-axis, and the Z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

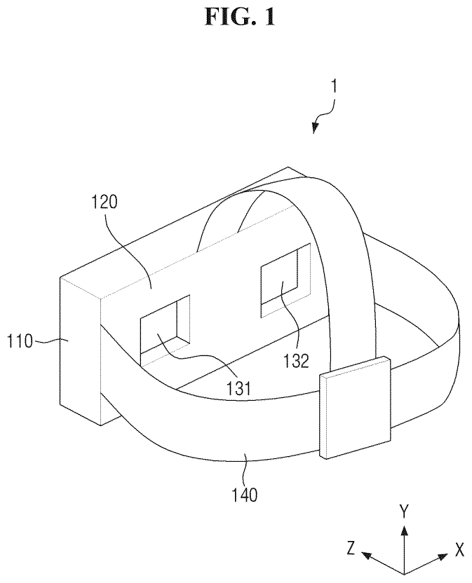

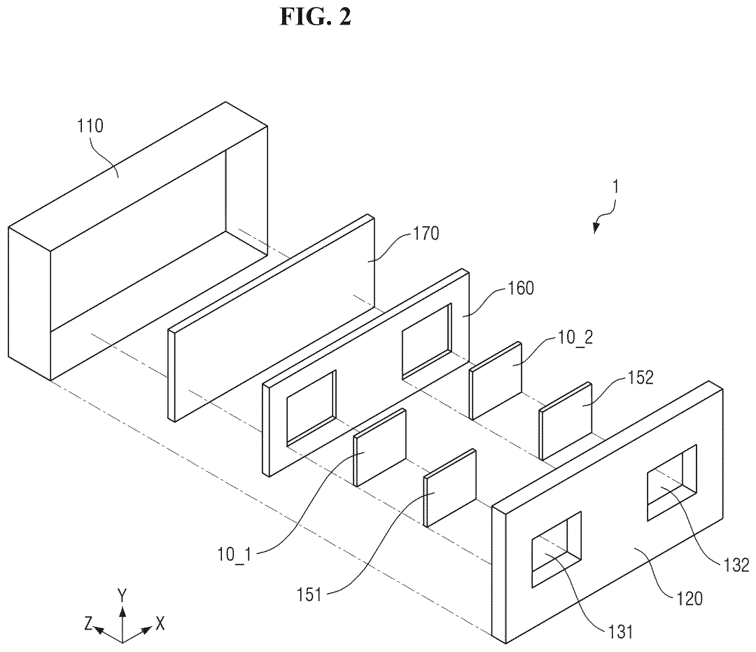

FIG. 1 is a perspective view illustrating a head mounted display device according to an embodiment. FIG. 2 is an exploded perspective view of the head mounted display device of FIG. 1.

Referring to FIGS. 1 and 2, a head mounted display device 1 according to an embodiment includes a first display device 10_1, a second display device 10_2, a display device accommodating portion 110, an accommodating portion cover 120, a first eyepiece 131, a second eyepiece 132, a head mounting band 140, a middle frame 160, a first optical member 151, a second optical member 152, a control circuit board 170, and a connector.

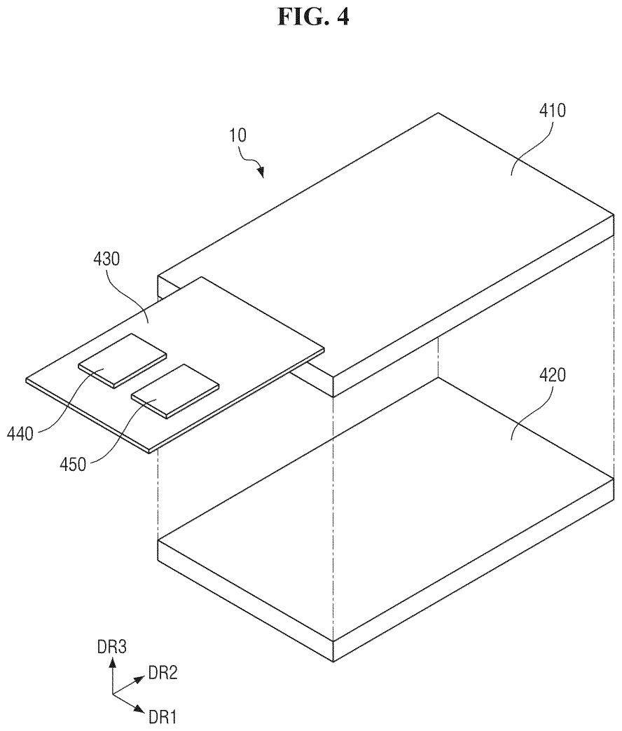

The first display device 10_1 provides an image to the user's left eye, and the second display device 10_2 provides an image to the user's right eye. Each of the first display device 10_1 and the second display device 10_2 is the same or substantially the same as a display device 10 described in more detail below with reference to FIGS. 4 through 18.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170, and may be disposed between the second display device 10_2 and the control circuit board 170. The middle frame 160 serves to support and fix the first display device 10_1, the second display device 10_2, and the control circuit board 170 to one another.

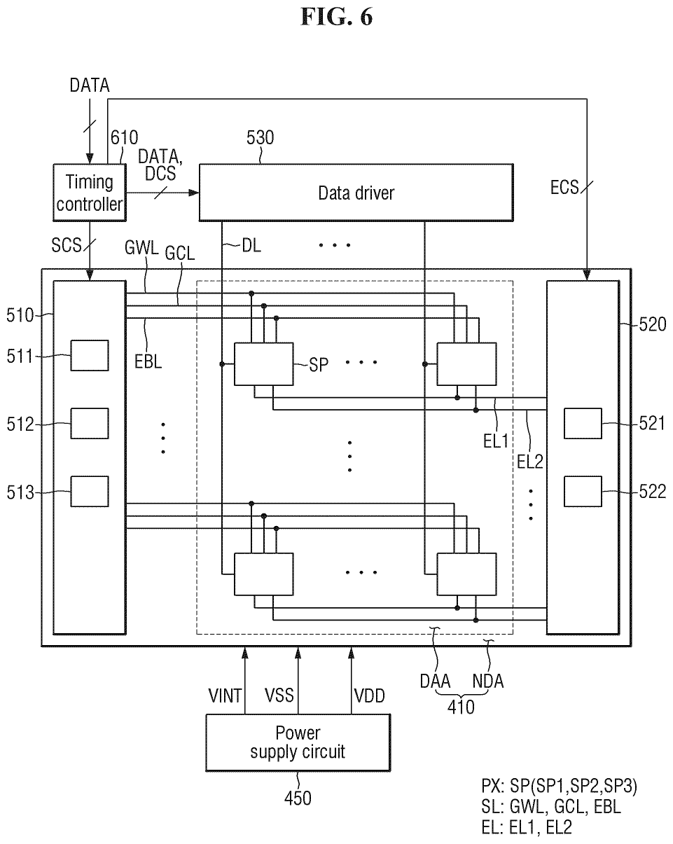

The control circuit board 170 may be disposed between the middle frame 160 and the display device accommodating portion 110. The control circuit board 170 may be connected to the first display device 10_1 and the second display device 10_2 through the connector. The control circuit board 170 may convert an image source input from the outside into digital video data DATA (see FIG. 6), and may transmit the digital video data DATA to the first display device 10_1 and the second display device 10_2 through the connector.

The control circuit board 170 may transmit the digital video data DATA corresponding to a left eye image optimized for the user's left eye to the first display device 10_1, and may transmit the digital video data DATA corresponding to a right eye image optimized for the user's right eye to the second display device 10_2. As another example, the control circuit board 170 may transmit the same digital video data DATA to the first display device 10_1 and the second display device 10_2.

The display device accommodating portion 110 serves to accommodate the first display device 10_1, the second display device 10_2, the middle frame 160, the first optical member 151, the second optical member 152, the control circuit board 170, and the connector. The accommodating portion cover 120 is disposed to cover one opened surface of the display device accommodating portion 110. The accommodating portion cover 120 may include the first eyepiece 131 where the user's left eye is to be disposed, and the second eyepiece 132 where the user's right eye is to be disposed. While FIGS. 1 and 2 illustrate that the first eyepiece 131 and the second eyepiece 132 are separately disposed, the present disclosure is not limited thereto. In some embodiments, the first eyepiece 131 and the second eyepiece 132 may be integrated together into one.

The first eyepiece 131 may be aligned with the first display device 10_1 and the first optical member 151. The second eyepiece 132 may be aligned with the second display device 10_2 and the second optical member 152. Therefore, the user may view an image of the first display device 10_1 magnified as a virtual image by the first optical member 151 through the first eyepiece 131, and may view an image of the second display device 10_2 magnified as a virtual image by the second optical member 152 through the second eyepiece 132.

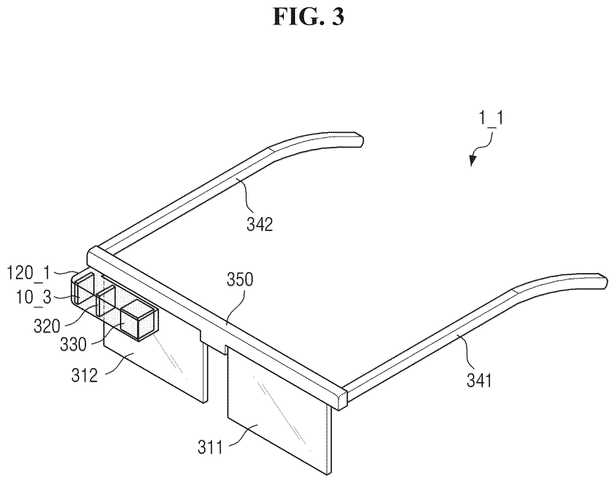

The head mounting band 140 serves to fix the display device accommodating portion 110 to the user's head, so that the first eyepiece 131 and the second eyepiece 132 of the accommodating portion cover 120 are disposed on the user's left and right eyes, respectively. When the display device accommodating portion 110 is implemented in a lightweight and small size, the head mounted display device 1 may include eyeglass frames, for example, as illustrated in FIG. 3, instead of the head mounting band 140.

In addition, the head mounted display device 1 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal. The wireless communication module may be a 5G communication module, a 4G communication module, a Wi-Fi module, or a Bluetooth module.

FIG. 3 is a perspective view illustrating a head mounted display device according to an embodiment.

Referring to FIG. 3, a head mounted display device 1_1 according to an embodiment may be a glasses-type display device including a display device accommodating portion 120_1 that is implemented in a relatively lightweight and smaller size. The head mounted display device 1_1 according to an embodiment may include a display device 10_3, a left eye lens 311, a right eye lens 312, a support frame 350, eyeglass frame legs 341 and 342, an optical member 320, a light path conversion member 330, and the display device accommodating portion 120_1.

The display device 10_3 illustrated in FIG. 3 may be the same or substantially the same as the display device 10 described in more detail below with reference to FIGS. 4 through 18.

The display device accommodating portion 120_1 may include the display device 10_3, the optical member 320, and the light path conversion member 330. As an image displayed on the display device 10_3 is magnified by the optical member 320, and a light path thereof is converted by the light path conversion member 330, the image may be provided to the user's right eye through the right eye lens 312. Accordingly, the user may view an augmented reality image in which a virtual image displayed on the display device 10_3 and a real image viewed through the right eye lens 312 are combined with each other through the right eye.

FIG. 3 illustrates that the display device accommodating portion 120_1 is disposed at a right distal end of the support frame 350, but the present disclosure is not limited thereto. For example, the display device accommodating portion 120_1 may be disposed at a left distal end of the support frame 350, and in this case, the image of the display device 10_3 may be provided to the user's left eye. As another example, the display device accommodating portions 120_1 may be disposed at both the left and right distal ends of the support frame 350. In this case, the user may view the image displayed on the display device 10_3 through both the user's left and right eyes.

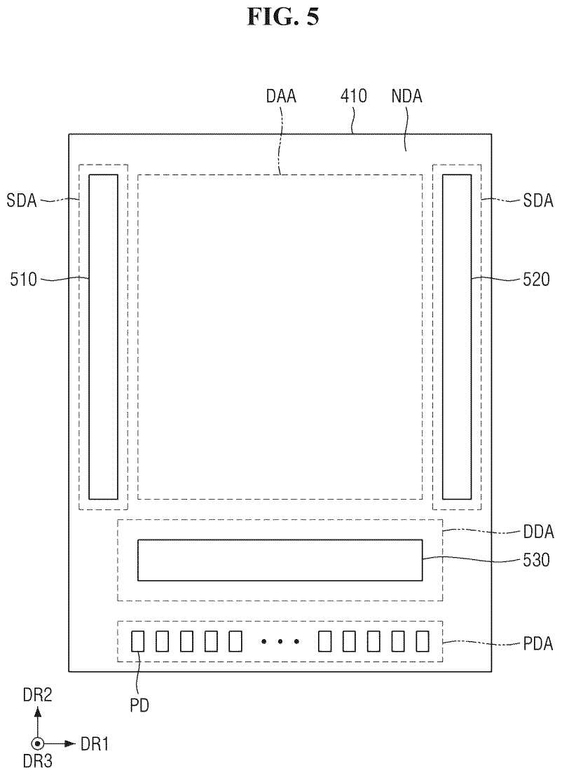

FIG. 4 is an exploded perspective view illustrating a display device according to an embodiment. FIG. 5 is a layout view illustrating a display panel of FIG. 4. FIG. 6 is a block diagram illustrating a display device according to an embodiment.

Referring to FIGS. 4 and 5, a display device 10 according to an embodiment is a device that displays a moving image and/or a still image. The display device 10 according to an embodiment may be applied to various suitable portable electronic devices, such as a mobile phone, a smart phone, a tablet personal computer (PC), a mobile communication terminal, an electronic notebook, an electronic book, a portable multimedia player (PMP), a navigation device, and an ultra mobile PC (UMPC). For example, the display device 10 may be applied to a display unit of a television, a laptop computer, a monitor, a billboard, or the Internet of Things (IoT) device. As another example, the display device 10 may be applied to a smart watch, a watch phone, and/or a head mounted display (HMD) for implementing virtual reality and/or augmented reality.

The display device 10 according to an embodiment includes a display panel 410, a heat dissipation layer 420, a circuit board 430, a driving circuit 440, and a power supply circuit 450.

The display panel 410 may be formed in a planar or substantially planar shape similar to that of a quadrangle. For example, the display panel 410 may have a planar or substantially planar shape similar to that of a quadrangle having short sides extending in a first direction DR1 and long sides extending in a second direction DR2 crossing or intersecting the first direction DR1. In the display panel 410, a corner where the short side extending in the first direction DR1 and the long side extending in the second direction DR2 meet each other may be rounded to have a suitable curvature (e.g., a predetermined curvature), or may be formed at a right angle. The planar shape of the display panel 410 is not limited to the quadrangle, and may be formed similarly to other suitable polygons, circles, or ovals. A planar shape of the display device 10 may follow the planar shape of the display panel 410, but the present disclosure is not limited thereto.

As illustrated in FIG. 5, the display panel 410 includes a display area DAA for displaying an image, and a non-display area NDA that does not display an image.

As illustrated in FIG. 6, the display area DAA includes a plurality of pixels PX, a plurality of scan lines SL, a plurality of emission control lines EL, and a plurality of data lines DL.

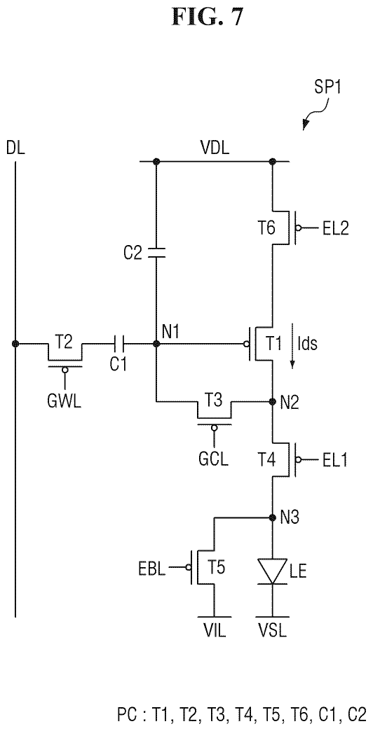

The plurality of pixels PX include a light emitting element LE (see FIG. 7) that emits light. The plurality of pixels PX may be arranged in a matrix form along the first direction DR1 and the second direction DR2. The plurality of scan lines SL and the plurality of emission control lines EL may extend in the first direction DR1, and may be disposed along the second direction DR2. The plurality of data lines DL may extend in the second direction DR2, and may be disposed along the first direction DR1.

The plurality of scan lines SL includes a plurality of write scan lines GWL, a plurality of control scan lines GCL, and a plurality of bias scan lines EBL. The plurality of emission control lines EL include a plurality of first emission control lines EL1 and a plurality of second emission control lines EL2.

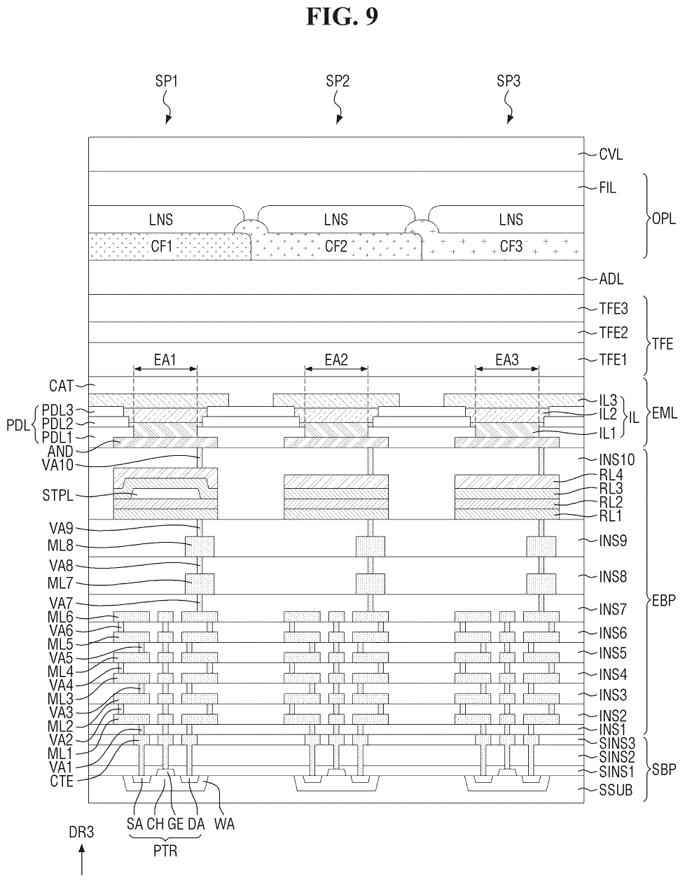

Each of the plurality of pixels PX includes a plurality of sub-pixels SP, for example, a plurality of sub-pixels SP1, SP2, and SP3. The plurality of sub-pixels SP1, SP2, and SP3 may include a plurality of pixel transistors as illustrated in FIG. 7. The plurality of pixel transistors may be formed through a semiconductor process, and may be disposed at (e.g., in or on) a semiconductor substrate (e.g., SSUB in FIG. 9). For example, the plurality of pixel transistors may be formed of a complementary metal oxide semiconductor (CMOS).

Each of the plurality of sub-pixels SP1, SP2, and SP3 may be connected to one write scan line GWL from among the plurality of write scan lines GWL, one control scan line GCL from among the plurality of control scan lines GCL, one bias scan line EBL from among the plurality of bias scan lines EBL, one first emission control line EL1 from among the plurality of first emission control lines EL1, one second emission control line EL2 from among the plurality of second emission control lines EL2, and one data line DL from among the plurality of data lines DL. Each of the plurality of sub-pixels SP1, SP2, and SP3 may receive a data voltage of a corresponding data line DL according to a write scan signal of a corresponding write scan line GWL, and may emit light from a corresponding light emitting element according to the data voltage.

The non-display area NDA includes a scan driving area SDA, a data driving area DDA, and a pad area PDA.

The scan driving area SDA may be an area in which a scan driver 510 and an emission driver 520 are disposed. FIG. 5 illustrates that the scan driver 510 is disposed on the left side of the display area DAA, and the emission driver 520 is disposed on the right side of the display area DAA, but the present disclosure is not limited thereto. For example, the scan driver 510 and the emission driver 520 may each be disposed on both the left and right sides of the display area DAA.

The scan driver 510 includes a plurality of scan transistors, and the emission driver 520 includes a plurality of light emitting transistors. The plurality of scan transistors and the plurality of light emitting transistors may be formed through a semiconductor process, and may be formed at (e.g., in or on) a semiconductor substrate (e.g., SSUB in FIG. 9). For example, the plurality of scan transistors and the plurality of light emitting transistors may be formed of CMOS.

The scan driver 510 may include a write scan signal output unit (e.g., a write scan signal output circuit) 511, a control scan signal output unit (e.g., a control scan signal output circuit) 512, and a bias scan signal output unit (e.g., a bias scan signal output circuit) 513. Each of the write scan signal output unit 511, the control scan signal output unit 512, and the bias scan signal output unit 513 may receive a scan timing control signal SCS from a timing control circuit (e.g., a timing controller) 610. The write scan signal output unit 511 may generate write scan signals according to the scan timing control signal SCS of the timing control circuit 610, and sequentially output the write scan signals to the write scan lines GWL. The control scan signal output unit 512 may generate control scan signals according to the scan timing control signal SCS, and sequentially output the control scan signals to the control scan lines GCL. The bias scan signal output unit 513 may generate bias scan signals according to the scan timing control signal SCS, and sequentially output the bias scan signals to the bias scan lines EBL.

The emission driver 520 includes a first emission control driver 521 and a second emission control driver 522. Each of the first emission control driver 521 and the second emission control driver 522 may receive an emission timing control signal ECS from the timing control circuit 610. The first emission control driver 521 may generate first emission control signals according to the emission timing control signal ECS, and sequentially output the first emission control signals to the first emission control lines EL1. The second emission control driver 522 may generate second emission control signals according to the emission timing control signal ECS, and sequentially output the second emission control signals to the second emission control lines EL2.

The data driving area DDA may be an area in which a data driver 530 is disposed. The data driver 530 may include a plurality of data transistors. The plurality of data transistors may be formed through a semiconductor process, and may be formed at (e.g., in or on) a semiconductor substrate (e.g., SSUB in FIG. 9). For example, the plurality of data transistors may be formed of CMOS.

The data driver 530 may receive digital video data DATA and a data timing control signal DCS from the timing control circuit 610. The data driver 530 converts the digital video data DATA into analog data voltages according to the data timing control signal DCS, and outputs the converted analog data voltages to the data lines DL. In this case, the sub-pixels SP1, SP2, and SP3 may be selected by the scan write signals of the scan driver 510, and the data voltages may be supplied to the selected sub-pixels SP1, SP2, and SP3.

The pad area PDA includes a plurality of pads PD disposed along the first direction DR1. Each of the plurality of pads PD may be exposed without being covered by a cover layer (e.g., CVL in FIG. 9) and a polarizing plate.

The heat dissipation layer 420 may overlap with the display panel 410 in the third direction DR3, which is a thickness direction of the display panel 410. The heat dissipation layer 420 may be disposed on one surface of the display panel 410, for example, such as on a rear surface of the display panel 410. The heat dissipation layer 420 serves to dissipate heat generated from the display panel 410. The heat dissipation layer 420 may include a graphite layer, or a metal layer, such as silver (Ag), copper (Cu), or aluminum (AI), having high thermal conductivity.

The circuit board 430 may be electrically connected to the plurality of pads PD of the pad area PDA of the display panel 410 by using a conductive adhesive member, such as an anisotropic conductive film. The circuit board 430 may be a flexible printed circuit board having a flexible material, or a flexible film. FIG. 4 illustrates that the circuit board 430 is unfolded, but the circuit board 430 may be bent. In this case, one end of the circuit board 430 may be disposed on the rear surface of the display panel 410. The one end of the circuit board 430 may be an opposite end of the end of the circuit board 430 that is connected to the plurality of pads PD of the pad area PDA of the display panel 410 by using the conductive adhesive member.

The timing control circuit 610 (which may be implemented as part of the driving circuit 440 in FIG. 4) may receive digital video data DATA and timing signals from the outside. The driving circuit 440/timing control circuit 610 may generate the scan timing control signal SCS, the emission timing control signal ECS, and the data timing control signal DCS for controlling the display panel 410 according to the timing signals. The driving circuit 440/timing control circuit 610 may output the scan timing control signal SCS to the scan driver 510, and may output the emission timing control signal ECS to the emission driver 520. The driving circuit 440/timing control circuit 610 may output the digital video data DATA and the data timing control signal DCS to the data driver 530.

A power supply circuit 450 may generate a plurality of panel driving voltages according to an external power voltage. For example, the power supply circuit 450 may generate and supply a first driving voltage VSS, a second driving voltage VDD, and a third driving voltage VINT to the display panel 410. The first driving voltage VSS, the second driving voltage VDD, and the third driving voltage VINT will be described in more detail below with reference to FIG. 7.

Each of the driving circuit 440/timing control circuit 610 and the power supply circuit 450 may be formed as an integrated circuit (IC), and may be attached to one surface of the circuit board 430. The scan timing control signal SCS, the emission timing control signal ECS, the digital video data DATA, and the data timing control signal DCS of the driving circuit 440/timing control circuit 610 may be supplied to the display panel 410 through the circuit board 430. The first driving voltage VSS, the second driving voltage VDD, and the third driving voltage VINT of the power supply circuit 450 may be supplied to the display panel 410 through the circuit board 430.

FIG. 7 is an equivalent circuit diagram of a first sub-pixel according to an embodiment.

Referring to FIG. 7, the first sub-pixel SP1 may be connected to the write scan line GWL, the control scan line GCL, the bias scan line EBL, the first emission control line EL1, the second emission control line EL2, and the data line DL. In addition, the first sub-pixel SP1 may be connected to a first driving voltage line VSL to which the first driving voltage VSS (see FIG. 6) corresponding to a low potential voltage is applied, a second driving voltage line VDL to which the second driving voltage VDD (see FIG. 6) corresponding to a high potential voltage is applied, and a third driving voltage line VIL to which the third driving voltage VINT (see FIG. 6) corresponding to an initialization voltage is applied. In other words, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be a voltage higher than the third driving voltage VINT.

The first sub-pixel SP1 includes a light emitting element LE, and a pixel driving circuit PC connected to the light emitting element LE. The pixel driving circuit PC includes a plurality of transistors T1 to T6, a first capacitor C1, and a second capacitor C2.

The light emitting element LE emits light according to a driving current Ids flowing through a channel of a first transistor T1. An amount of light emitted from the light emitting element LE may be proportional to the driving current Ids. The light emitting element LE may be disposed between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode electrode (e.g., a pixel electrode), and the second electrode of the light emitting element LE may be a cathode electrode (e.g., a common electrode). The light emitting element LE may be an organic light emitting diode including the first electrode, the second electrode, and an organic light emitting layer disposed between the first electrode and the second electrode, but the present disclosure is not limited thereto. For example, the light emitting element LE may be an inorganic light emitting device including a first electrode, a second electrode, and an inorganic semiconductor disposed between the first electrode and the second electrode. In this case, the light emitting element LE may be a micro light emitting diode.

The first transistor T1 may be a driving transistor that controls a source-drain current (hereinafter, referred to as the “driving current” Ids) flowing between a source electrode and a drain electrode thereof according to a voltage applied to a gate electrode thereof. The first transistor T1 includes the gate electrode connected to a first node N1, the source electrode connected to a drain electrode of a sixth transistor T6, and the drain electrode connected to a second node N2.

The second transistor T2 may be disposed between one electrode of the first capacitor C1 and the data line DL. The second transistor T2 may be turned on by the write scan signal of the write scan line GWL, and connects the one electrode of the first capacitor C1 to the data line DL. Accordingly, the data voltage of the data line DL may be applied to the one electrode of the first capacitor C1. The second transistor T2 includes a gate electrode connected to the write scan line GWL, a source electrode connected to the data line DL, and a drain electrode connected to the one electrode of the first capacitor C1.

The third transistor T3 may be disposed between the first node N1 and the second node N2. The third transistor T3 may be turned on by the control scan signal of the control scan line GCL to connect the first node N1 to the second node N2. Accordingly, because the gate electrode and the drain electrode of the first transistor T1 are connected to each other by the third transistor T3, the first transistor T1 may operate like a diode. In other words, the first transistor T1 may be diode-connected when the third transistor T3 is turned on. The third transistor T3 includes a gate electrode connected to the control scan line GCL, a source electrode connected to the second node N2, and a drain electrode connected to the first node N1.

The fourth transistor T4 may be disposed between the second node N2 and a third node N3. The fourth transistor T4 may be turned on by the first emission control signal of the first emission control line EL1, and connects the second node N2 to the third node N3. Accordingly, the driving current Ids of the first transistor T1 may be supplied to the light emitting element LE. The fourth transistor T4 includes a gate electrode connected to the first emission control line EL1, a source electrode connected to the second node N2, and a drain electrode connected to the third node N3.

The fifth transistor T5 may be disposed between the third node N3 and the third driving voltage line VIL. The fifth transistor T5 may be turned on by the bias scan signal of the bias scan line EBL, and connects the third node N3 to the third driving voltage line VIL. Accordingly, the third driving voltage VINT of the third driving voltage line VIL may be applied to the first electrode of the light emitting element LE. The fifth transistor T5 includes a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by the second emission control signal of the second emission control line EL2, and connects the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor C1 is formed between the first node N1 and the drain electrode of the second transistor T2. The first capacitor C1 includes the one electrode connected to the drain electrode of the second transistor T2, and another electrode connected to the first node N1.

The second capacitor C2 is formed between the gate electrode of the first transistor T1 and the second driving voltage line VDL. The second capacitor C2 includes one electrode connected to the gate electrode of the first transistor T1, and another electrode connected to the second driving voltage line VDL.

The first node N1 may be a contact point of the gate electrode of the first transistor T1, the drain electrode of the third transistor T3, the other electrode of the first capacitor C1, and the one electrode of the second capacitor C2. The second node N2 may be a contact point of the drain electrode of the first transistor T1, the source electrode of the third transistor T3, and the source electrode of the fourth transistor T4. The third node N3 may be a contact point of the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET (PMOS), but the present disclosure is not limited thereto. As another example, each of the first to sixth transistors T1 to T6 may be an N-type MOSFET (NMOS). As another example, each of some of the first to sixth transistors T1 to T6 may be a P-type MOSFET (PMOS), and each of the other remaining transistors may be an N-type MOSFET (NMOS).

FIG. 7 illustrates that the first sub-pixel SP1 includes the six transistors T1 to T6 and the two capacitors C1 and C2, but the present disclosure is not limited thereto. For example, the number of transistors and the number of capacitors of the first sub-pixel SP1 are not limited to those illustrated in FIG. 7, and may be variously modified as needed or desired.

In addition, the equivalent circuit diagram of the second sub-pixel SP2 and the equivalent circuit diagram of the third sub-pixel SP3 may be the same or substantially the same as the equivalent circuit diagram of the first sub-pixel SP1 described above with reference to FIG. 7. Therefore, redundant description of the equivalent circuit diagram of the second sub-pixel SP2 and the equivalent circuit diagram of the third sub-pixel SP3 may not be repeated.

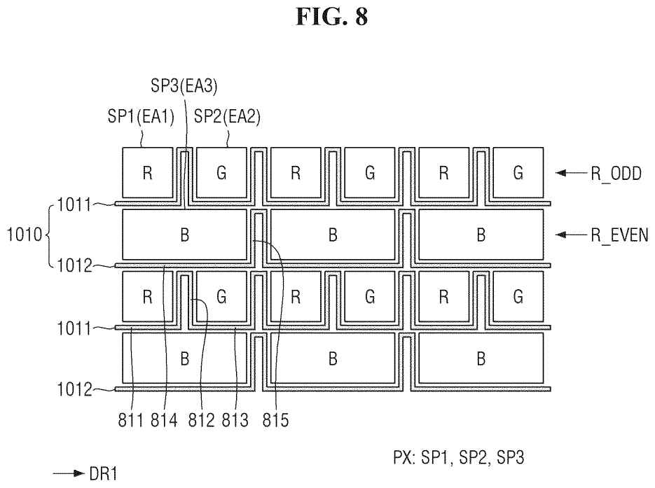

FIG. 8 is a layout view illustrating pixels of a display area according to an embodiment.

Referring to FIG. 8, each of the plurality of pixels PX includes a first light emitting area EA1, which is a light emitting area of the corresponding first sub-pixel SP1, a second light emitting area EA2, which is a light emitting area of the corresponding second sub-pixel SP2, and a third light emitting area EA3, which is a light emitting area of the corresponding third sub-pixel SP3.

Each of the first light emitting area EA1, the second light emitting area EA2, and the third light emitting area EA3 may have a quadrangular planar shape, such as a rectangle, a square, or a rhombus.

In an odd row R_ODD in which some of the plurality of sub-pixels SP1, SP2, and SP3 are disposed, the first light emitting area EA1 and the second light emitting area EA2 may be alternately disposed along the first direction DR1.

In an even row R_EVEN in which some of the plurality of sub-pixels SP1, SP2, and SP3 are disposed, the third light emitting area EA3 may be disposed at suitable intervals along the first direction DR1. A length of the third light emitting area EA3 in the first direction DR1 may be greater than a sum of a length of the first light emitting area EA1 in the first direction DR1 and a length of the second light emitting area EA2 in the first direction DR1. For example, the first direction DR1 may be a horizontal direction in the illustrated examples.

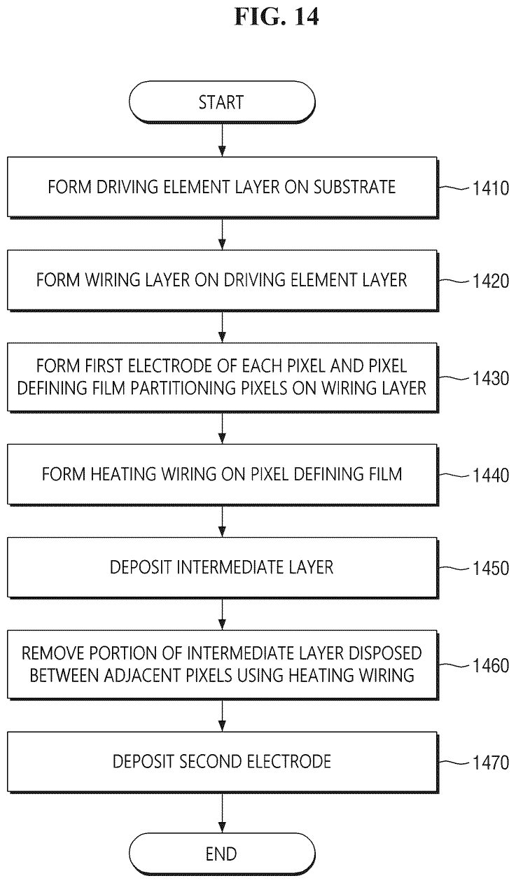

According to an embodiment, the display panel 410 (see FIG. 4) may include a reference wiring 1010 extending in the first direction DR1, while surrounding (e.g., around peripheries of) the light emitting areas EA1, EA2, and EA3. The reference wiring 1010 serves to disconnect a portion of the intermediate layer IL (see FIG. 9) disposed between the sub-pixels SP1, SP2, and SP3 that are disposed to be adjacent to each other during a manufacturing process of the display panel 410. A method of disconnecting the intermediate layer IL using the reference wiring 1010 will be described in more detail below with reference to FIGS. 14 through 18. Hereinafter, the reference wiring may also be referred to as “wirings”, a “heating wiring”, a “cross wiring”, or a “dummy wiring”.

According to an embodiment, the reference wiring (e.g., wirings) 1010 may include a first reference wiring (e.g., first wiring) 1011 having a first length in the display area DAA (see FIG. 5), and a second reference wiring (e.g., second wiring) 1012 having a second length in the display area DAA. In this case, the first length may be longer than the second length. Therefore, a resistance of the first reference wiring 1011 in the display area DAA may be greater than a resistance of the second reference wiring 1012, because the length of the first reference wiring 1011 may be longer than the length of the second reference wiring 1012.

The first reference wiring 1011 may be disposed to extend in the first direction DR1, while surrounding (e.g., around peripheries of) the first and second light emitting areas EA1 and EA2. The second reference wiring 1012 may be disposed to extend in the first direction DR1, while surrounding (e.g., around peripheries of) the third light emitting areas EA3. Because a length of one third light emitting area EA3 in the first direction DR1 may be substantially the same as the sum of the length of the first light emitting area EA1 in the first direction DR1 and the length of the second light emitting area EA2 in the first direction DR1, the first reference wiring 1011 may be longer than the second reference wiring 1012.

In more detail, the first reference wiring 1011 may include a first portion 811 disposed between the first light emitting area EA1 and the third light emitting area EA3, a second portion 812 extending from the first portion 811 and disposed between the first light emitting area EA1 and the second light emitting area EA2, and a third portion 813 extending from the second portion 812 and disposed between the second light emitting area EA2 and the third light emitting area EA3. The second reference wiring 1012 may include a fourth portion 814 disposed between the third light emitting area EA3 and the first and second light emitting areas EA1 and EA2, and a fifth portion 815 disposed between the third light emitting areas EA3 that are disposed to be adjacent to each other.

A length deviation or variation between the first and second reference wirings 1011 and 1012 may be the cause of a resistance deviation or variation between the first and second reference wirings 1011 and 1012. The resistance deviation or variation between the first and second reference wirings 1011 and 1012 may cause the width and the height of a disconnected portion of the intermediate layer IL (e.g., at which the intermediate layer IL is disconnected) to be uneven.

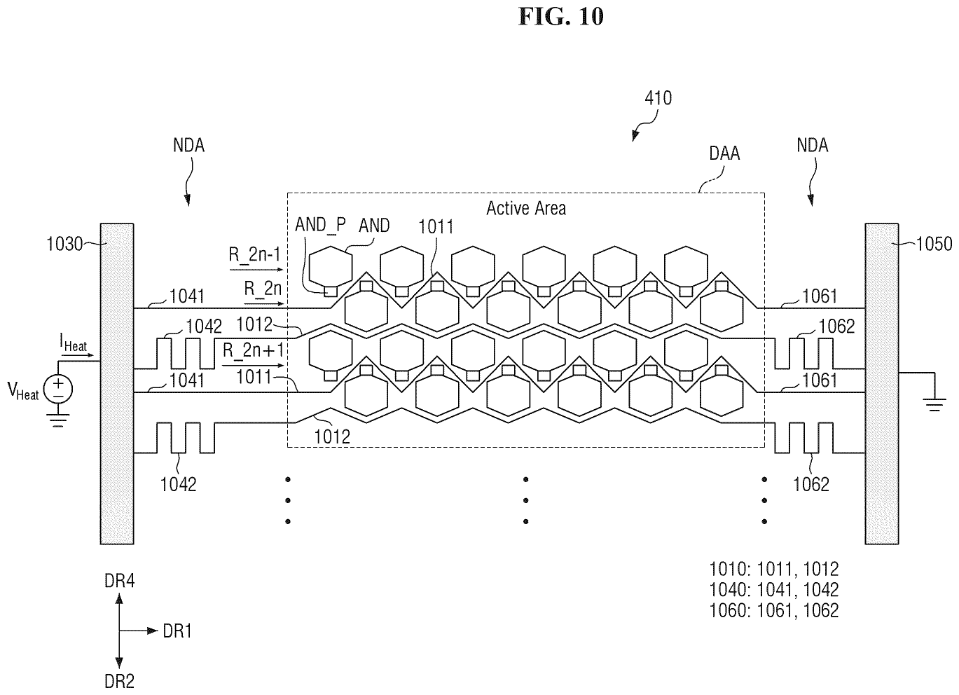

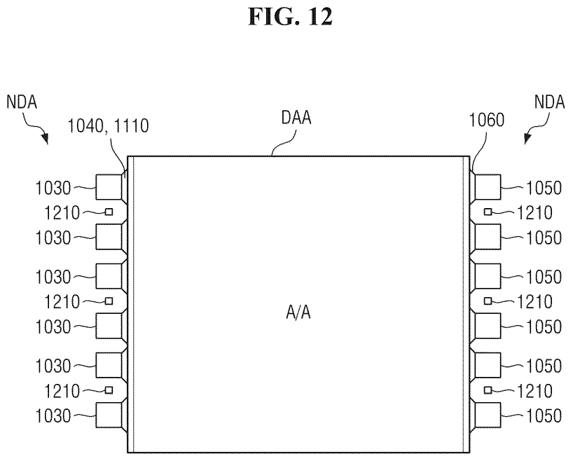

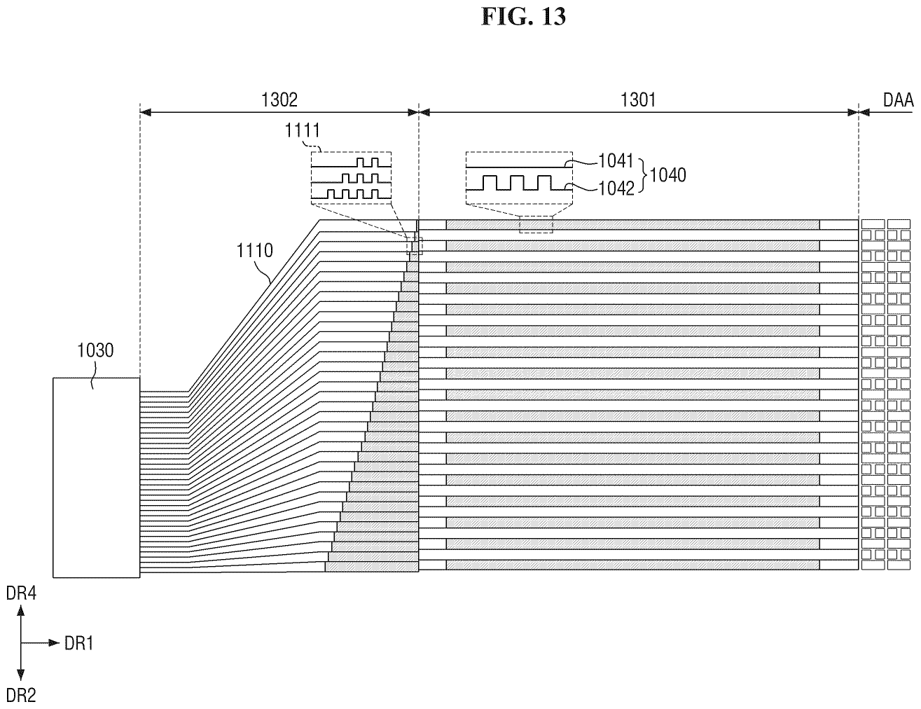

According to an embodiment of the present disclosure, a metal pattern wiring (e.g., pattern wirings) (e.g., see 1040 in FIG. 10) connected to the reference wiring and a length deviation compensation portion (e.g., see 1111 in FIG. 13) may be disposed in the non-display area to compensate for the length deviation or variation between the first and second reference wirings 1011 and 1012 in the display area. For example, as the resistance deviation or variation between the first and second reference wirings 1011 and 1012 occurs in the display area DAA, because the metal pattern wiring 1040 and the length deviation compensation portion 1111 may be disposed in the non-display area NDA (see FIG. 5) to compensate for the resistance deviation or variation, the total length and total resistance from each reference wiring 1010 to the power pad (e.g., see 1030 in FIG. 10) may be made to be uniform or substantially uniform. The metal pattern wiring 1040 will be described in more detail below with reference to FIG. 10. The length deviation compensation portion 1111 will be described in more detail below with reference to FIGS. 12 and 13. Hereinafter, the metal pattern wiring may be referred to as “pattern wirings”, a “compensation wiring” or an “extension wiring.”

FIG. 8 illustrates that each of the first light emitting area EA1, the second light emitting area EA2, and the third light emitting area EA3 has a quadrangular planar shape, but the present disclosure is not limited thereto. For example, each of the first light emitting area EA1, the second light emitting area EA2, and the third light emitting area EA3 may have a polygonal planar shape, a circular planar shape, or an elliptical planar shape other than the quadrangular shape.

The first light emitting area EA1 may emit light of a first color, the second light emitting area EA2 may emit light of a second color, and the third light emitting area EA3 may emit light of a third color. For example, the light of the first color may be light in a red wavelength band, the light of the second color may be light in a green wavelength band, and the light of the third color may be light in a blue wavelength band.

FIG. 8 illustrates that each of the plurality of pixels PX includes three light emitting areas EA1, EA2, and EA3, but the present disclosure is not limited thereto. In other words, in some embodiments, each of the plurality of pixels PX may include four light emitting areas.

In addition, the arrangement of the light emitting areas of the plurality of pixels PX is not limited to that illustrated in FIG. 8. For example, the light emitting areas of the plurality of pixels PX may be disposed in a stripe structure in which the light emitting areas are arranged along the first direction DR1, in an RGBG structure (e.g., a PENTILE® structure, PENTILE® being a duly registered trademark of Samsung Display, Co., Ltd.) in which the light emitting areas have a diamond arrangement, or in a hexagonal structure in which the light emitting areas having a hexagonal planar shape are arranged.

FIG. 9 is a cross-sectional view illustrating an example in which a portion of a display panel is cut according to an embodiment.

Referring to FIG. 9, the display panel 410 (see FIG. 4) includes a semiconductor backplane SBP, a light emitting element backplane EBP, a light emitting element layer EML, an encapsulation layer TFE, an optical layer OPL, a cover layer CVL, and a polarizing plate.

The semiconductor backplane SBP includes a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR. The plurality of pixel transistors PTR may be the first to sixth transistors T1 to T6 described above with reference to FIG. 7.

The semiconductor substrate SSUB may be a silicon substrate, a germanium substrate, or a silicon-germanium substrate. The semiconductor substrate SSUB may be a substrate doped with first-type impurities. A plurality of well areas WA may be disposed at (e.g., in or on) an upper surface of the semiconductor substrate SSUB. The plurality of well areas WA may be areas doped with second-type impurities. The second type impurity may be different from the first type impurity described above. For example, when the first-type impurity is a p-type impurity, the second-type impurity may be an n-type impurity. As another example, when the first-type impurity is an n-type impurity, the second-type impurity may be a p-type impurity.

Each of the plurality of well areas WA includes a source area SA corresponding to a source electrode of the pixel transistor PTR, a drain area DA corresponding to a drain electrode of the pixel transistor PTR, and a channel area CH disposed between the source area SA and the drain area DA.

Each of the source area SA and the drain area DA may be an area doped with first-type impurities. A gate electrode GE of the pixel transistor PTR may overlap with the well area WA in the third direction DR3. The channel area CH may overlap with the gate electrode GE in the third direction DR3. The source area SA may be disposed on one side of the gate electrode GE, and the drain area DA may be disposed on another side (e.g., an opposite side) of the gate electrode GE.

Each of the plurality of well areas WA further includes a first low-concentration impurity area disposed between the channel area CH and the source area SA, and a second low-concentration impurity area disposed between the channel area CH and the drain area DA. The first low-concentration impurity area may be an area having an impurity concentration lower than that of the source area SA. The second low-concentration impurity area may be an area having an impurity concentration lower than that of the drain area DA. A distance between the source area SA and the drain area DA may be increased by the first low-concentration impurity area and the second low-concentration impurity area. Therefore, because a length of the channel area CH of each of the pixel transistors PTR may be increased, a punch-through phenomena and a hot carrier phenomena that may be caused by a shorter channel may be prevented or substantially prevented.

A first semiconductor insulating film SINS1 may be disposed on the semiconductor substrate SSUB. The first semiconductor insulating film SINS1 may be formed as a silicon carbon nitride (SiCN) or silicon oxide (SiOₓ)-based inorganic film, but the present disclosure is not limited thereto.

A second semiconductor insulating film SINS2 may be disposed on the first semiconductor insulating film SINS1. The second semiconductor insulating film SINS2 may be formed as a silicon oxide (SiOₓ)-based inorganic film, but the present disclosure is not limited thereto.

The plurality of contact terminals CTE may be disposed on the second semiconductor insulating film SINS2. Each of the plurality of contact terminals CTE may be connected to one of the gate electrode GE, the source area SA, and the drain area DA of each of the plurality of pixel transistors PTR through a corresponding hole penetrating through the first semiconductor insulating film SINS1 and the second semiconductor insulating film SINS2. The plurality of contact terminals CTE may be formed of one of copper (Cu), aluminum (Al), tungsten (W), molybdenum (Mo), chromium (Cr), gold (Au), titanium (Ti), nickel (Ni), and neodymium (Nd), or a suitable alloy including at least one thereof.

A third semiconductor insulating film SINS3 may be disposed on a side surface of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but the present disclosure is not limited thereto.

The semiconductor substrate SSUB may be replaced with a glass substrate or a polymer resin substrate such as polyimide. In this case, the thin film transistors may be disposed on the glass substrate or the polymer resin substrate. The glass substrate may be a rigid substrate that is not bent, and the polymer resin substrate may be a flexible substrate that may be bent or curved.

The light emitting element backplane EBP includes first to eighth metal layers ML1 to ML8, reflective metal layers RL1 to RL4, a plurality of vias VA1 to VA10, and a step layer STPL. In addition, the light emitting element backplane EBP includes a plurality of interlayer insulating films INS1 to INS10 disposed between semiconductor backplane SBP, the first to eighth metal layers ML1 to ML8, reflective electrodes RL1 to RL4, and the light emitting element layer EML.

The first to eighth metal layers ML1 to ML8 serve to implement the circuit of the first sub-pixel SP1 illustrated in FIG. 7 by connecting to the plurality of contact terminals CTE exposed from the semiconductor backplane SBP. In other words, only the first to sixth transistors T1 to T6 are formed at (e.g., in or on) the semiconductor backplane SBP, and the first to sixth transistors T1 to T6 and the first and second capacitors C1 and C2 are connected through the first to eighth metal layers ML1 to ML8. In addition, the drain area corresponding to the drain electrode of the fourth transistor T4, the source area corresponding to the source electrode of the fifth transistor T5, and the first electrode of the light emitting element LE are also connected through the first to eighth metal layers ML1 to ML8.

A first interlayer insulating film INS1 may be disposed on the semiconductor backplane SBP. Each of the first vias VA1 may penetrate through the first interlayer insulating film INS1, and be connected to the corresponding contact terminal CTE exposed from the semiconductor backplane SBP. Each of the first metal layers ML1 may be disposed on the first interlayer insulating film INS1, and may be connected to the corresponding first via VA1.

A second interlayer insulating film INS2 may be disposed on the first interlayer insulating film INS1 and the first metal layers ML1. Each of the second vias VA2 may be connected to the corresponding first metal layer ML1 exposed by penetrating through the second interlayer insulating film INS2. Each of the second metal layers ML2 may be disposed on the second interlayer insulating film INS2, and may be connected to the corresponding second via VA2.

A third interlayer insulating film INS3 may be disposed on the second interlayer insulating film INS2 and the second metal layers ML2. Each of the third vias VA3 may be connected to the corresponding second metal layer ML2 exposed by penetrating through the third interlayer insulating film INS3. Each of the third metal layers ML3 may be disposed on the third interlayer insulating film INS3, and may be connected to the corresponding third via VA3.

A fourth interlayer insulating film INS4 may be disposed on the third interlayer insulating film INS3 and the third metal layers ML3. Each of the fourth vias VA4 may be connected to the corresponding third metal layer ML3 exposed by penetrating through the fourth interlayer insulating film INS4. Each of the fourth metal layers ML4 may be disposed on the fourth interlayer insulating film INS4, and may be connected to the corresponding fourth via VA4.

A fifth interlayer insulating film INS5 may be disposed on the fourth interlayer insulating film INS4 and the fourth metal layers ML4. Each of the fifth vias VA5 may be connected to the corresponding fourth metal layer ML4 exposed by penetrating through the fifth interlayer insulating film INS5. Each of the fifth metal layers ML5 may be disposed on the fifth interlayer insulating film INS5, and may be connected to the corresponding fifth via VA5.

A sixth interlayer insulating film INS6 may be disposed on the fifth interlayer insulating film INS5 and the fifth metal layers ML5. Each of the sixth vias VA6 may be connected to the corresponding fifth metal layer ML5 exposed by penetrating through the sixth interlayer insulating film INS6. Each of the sixth metal layers ML6 may be disposed on the sixth interlayer insulating film INS6, and may be connected to the corresponding sixth via VA6.

A seventh interlayer insulating film INS7 may be disposed on the sixth interlayer insulating film INS6 and the sixth metal layers ML6. Each of the seventh vias VA7 may be connected to the corresponding sixth metal layer ML6 exposed by penetrating through the seventh interlayer insulating film INS7. Each of the seventh metal layers ML7 may be disposed on the seventh interlayer insulating film INS7, and may be connected to the corresponding seventh via VA7.

An eighth interlayer insulating film INS8 may be disposed on the seventh interlayer insulating film INS7 and the seventh metal layers ML7. Each of the eighth vias VA8 may be connected to the corresponding seventh metal layer ML7 exposed by penetrating through the eighth interlayer insulating film INS8. Each of the eighth metal layers ML8 may be disposed on the eighth interlayer insulating film INS8, and may be connected to the corresponding eighth via VA8.

The first to eighth metal layers ML1 to ML8 and the first to eighth vias VA1 to VA8 may be formed of the same or substantially the same material as each other. The first to eighth metal layers ML1 to ML8 and the first to eighth vias VA1 to VA8 may be formed of one of copper (Cu), aluminum (AI), tungsten (W), molybdenum (Mo), chromium (Cr), gold (Au), titanium (Ti), nickel (Ni), and neodymium (Nd), or a suitable alloy including at least one thereof. The first to eighth vias VA1 to VA8 may be formed of the same or substantially the same material as each other. The first to eighth interlayer insulating films INS1 to INS8 may be formed as a silicon oxide (SiOₓ)-based inorganic film, but the present disclosure is not limited thereto.

A thickness of the first metal layer ML1, a thickness of the second metal layer ML2, a thickness of the third metal layer ML3, a thickness of the fourth metal layer ML4, a thickness of the fifth metal layer ML5, and a thickness of the sixth metal layer ML6 may be greater than a thickness of the first via VA1, a thickness of the second via VA2, a thickness of the third via VA3, a thickness of the fourth via VA4, a thickness of the fifth via VA5, and a thickness of the sixth via VA6, respectively. Each of the thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be the same or substantially the same as each other. For example, the thickness of the first metal layer ML1 may be approximately 1360 Å, each of the thickness of the second metal layer ML2, the thickness of the third metal layer ML3, the thickness of the fourth metal layer ML4, the thickness of the fifth metal layer ML5, and the thickness of the sixth metal layer ML6 may be approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 may be 1150 Å.

Each of a thickness of the seventh metal layer ML7 and a thickness of the eighth metal layer ML8 may be greater than each of the thickness of the first metal layer ML1, the thickness of the second metal layer ML2, the thickness of the third metal layer ML3, the thickness of the fourth metal layer ML4, the thickness of the fifth metal layer ML5, and the thickness of the sixth metal layer ML6. Each of the thickness of the seventh metal layer ML7 and the thickness of the eighth metal layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be the same or substantially the same as each other. For example, each of the thickness of the seventh metal layer ML7 and the thickness of the eighth metal layer ML8 may be approximately 9000 Å. Each of the thicknesses of the seventh via VA7 and the eighth via VA8 may be approximately 6000 Å.

A ninth interlayer insulating film INS9 may be disposed on the eighth interlayer insulating film INS8 and the eighth metal layers ML8. The ninth interlayer insulating film INS9 may be formed as a silicon oxide (SiOₓ)-based inorganic film, but the present disclosure is not limited thereto.

Each of the ninth vias VA9 may be connected to the corresponding eighth metal layer ML8 exposed by penetrating through the ninth interlayer insulating film INS9. The ninth vias VA9 may be formed of one of copper (Cu), aluminum (AI), tungsten (W), molybdenum (Mo), chromium (Cr), gold (Au), titanium (Ti), nickel (Ni), and neodymium (Nd), or a suitable alloy including at least one thereof. A thickness of the ninth via VA9 may be approximately 16500 Å.

Each of first reflective electrodes RL1 may be disposed on the ninth interlayer insulating film INS9, and may be connected to the corresponding ninth via VA9. The first reflective electrodes RL1 may be formed of one of copper (Cu), aluminum (AI), tungsten (W), molybdenum (Mo), chromium (Cr), gold (Au), titanium (Ti), nickel (Ni), and neodymium (Nd), or a suitable alloy including at least one thereof. Each of the second reflective electrodes RL2 may be disposed on the corresponding first reflective electrode RL1. The second reflective electrodes RL2 may be formed of one of copper (Cu), aluminum (AI), tungsten (W), molybdenum (Mo), chromium (Cr), gold (Au), titanium (Ti), nickel (Ni), and neodymium (Nd), or a suitable alloy including at least one thereof. For example, the second reflective electrodes RL2 may be formed of titanium nitride (TiN).

In the first sub-pixel SP1, the step layer STPL may be disposed on the second reflective electrode RL2. The step layer STPL may not be disposed in each of the second sub-pixel SP2 and the third sub-pixel SP3. A thickness of the step layer STPL may be determined (e.g., may be set) in consideration of a wavelength of the light of the first color, and a distance from a first light emitting layer to the corresponding fourth reflective electrode RL4, so that the light of the first color emitted from the first light emitting layer of the first sub-pixel SP1 may be reflected. The step layer STPL may be formed of a silicon carbon nitride (SiCN) or silicon oxide (SiOₓ)-based inorganic film, but the present disclosure is not limited thereto. The thickness of the step layer STPL may be approximately 400 Å.

In the first sub-pixel SP1, the third reflective electrode RL3 may be disposed on the second reflective electrode RL2 and the step layer STPL. In the second and third sub-pixels SP2 and SP3, the third reflective electrode RL3 may be disposed on the second reflective electrode RL2. The third reflective electrodes RL3 may be formed of one of copper (Cu), aluminum (Al), tungsten (W), molybdenum (Mo), chromium (Cr), gold (Au), titanium (Ti), nickel (Ni), and neodymium (Nd), or a suitable alloy including at least one thereof.

At least one of the first reflective electrode RL1, the second reflective electrode RL2, and the third reflective electrode RL3 may be omitted as needed or desired.

Each of fourth reflective electrodes RL4 may be disposed on the corresponding third reflective electrode RL3. The fourth reflective electrodes RL4 may be layers that reflect light from first to third intermediate layers IL1, IL2, and IL3. The fourth reflective electrodes RL4 may include a suitable metal having a high reflectance for reflecting light. The fourth reflective electrode RL4 may be formed of aluminum (Al), a stacked structure (Ti/Al/Ti) of aluminum and titanium, a stacked structure (ITO/AI/ITO) of aluminum and ITO, an APC alloy, which is an alloy of silver (Ag), palladium (Pd), and copper (Cu), and/or a stacked structure (ITO/APC/ITO) of an APC alloy and ITO, but the present disclosure is not limited thereto. A thickness of each of the fourth reflective electrodes RL4 may be approximately 850 Å.

A tenth interlayer insulating film INS10 may be disposed on the ninth interlayer insulating film INS9 and the fourth reflective electrodes RL4. The tenth interlayer insulating film INS10 may be formed as a silicon oxide (SiOₓ)-based inorganic film, but the present disclosure is not limited thereto.

Each of the tenth vias VA10 may be connected to the corresponding ninth metal layer ML9 exposed by penetrating through the tenth interlayer insulating film INS10. The tenth vias VA10 may be formed of one of copper (Cu), aluminum (AI), tungsten (W), molybdenum (Mo), chromium (Cr), gold (Au), titanium (Ti), nickel (Ni), and neodymium (Nd), or a suitable alloy including at least one thereof. Due to the step layer STPL, a thickness of the tenth via VA10 in the first sub-pixel SP1 may be smaller than a thickness of the tenth via VA10 in each of the second and third sub-pixels SP2 and SP3. For example, the thickness of the tenth via VA10 in the first sub-pixel SP1 may be approximately 800 Å, and the thickness of the tenth via VA10 in each of the second and third sub-pixels SP2 and SP3 may be approximately 1200 Å.

The light emitting element layer EML may be disposed on the light emitting element backplane EBP. The light emitting element layer EML may include a plurality of light emitting elements LE (see FIG. 7), each including a first electrode AND, an intermediate layer IL, and a second electrode CAT, and a pixel defining layer PDL.

The first electrode AND of each of the light emitting elements LE may be disposed on the tenth interlayer insulating film INS10, and may be connected to the corresponding tenth via VA10. The first electrode AND of each of the light emitting elements LE may be connected to the drain area DA or the source area SA of the corresponding pixel transistor PTR through the corresponding tenth via VA10, the corresponding first to fourth reflective electrodes RL1 to RL4, the corresponding first to ninth vias VA1 to VA9, the corresponding first to eighth metal layers ML1 to ML8, and the corresponding contact terminal CTE. The first electrode AND of each of the light emitting elements LE may be formed of one of copper (Cu), aluminum (Al), tungsten (W), molybdenum (Mo), chromium (Cr), gold (Au), titanium (Ti), nickel (Ni), and neodymium (Nd), or a suitable alloy including at least one thereof. For example, the first electrode AND of each of the light emitting elements LE may be formed of titanium nitride (TiN).

The pixel defining layer PDL may be disposed on a partial area of the first electrode AND of each of the light emitting elements LE. The pixel defining layer PDL may cover an edge of the first electrode AND of each of the light emitting elements LE. The pixel defining layer PDL serves to partition the first light emitting areas EA1, the second light emitting areas EA2, and the third light emitting areas EA3.

The first light emitting area EA1 may be defined as an area in which the first electrode AND, the intermediate layer IL, and the second electrode CAT are sequentially stacked on one another in the first sub-pixel SP1 to emit light. The second light emitting area EA2 may be defined as an area in which the first electrode AND, the intermediate layer IL, and the second electrode CAT are sequentially stacked on one another in the second sub-pixel SP2 to emit light. The third light emitting area EA3 may be defined as an area in which the first electrode AND, the intermediate layer IL, and the second electrode CAT are sequentially stacked on one another in the third sub-pixel SP3 to emit light.

The pixel defining layer PDL may include first to third pixel defining layers PDL1, PDL2, and PDL3. The first pixel defining layer PDL1 may be disposed on the edge of the first electrode AND of each of the light emitting elements LE. The second pixel defining layer PDL2 may be disposed on the first pixel defining layer PDL1. The third pixel defining layer PDL3 may be disposed on the second pixel defining layer PDL2. The first pixel defining layer PDL1, the second pixel defining layer PDL2, and the third pixel defining layer PDL3 may be formed as a silicon oxide (SiOₓ)-based inorganic film, but the present disclosure is not limited thereto. Each of a thickness of the first pixel defining layer PDL1, a thickness of the second pixel defining layer PDL2, and a thickness of the third pixel defining layer PDL3 may be approximately 500 Å.

The intermediate layer IL may include a first intermediate layer IL1, a second intermediate layer IL2, and a third intermediate layer IL3.

The intermediate layer IL may have a tandem structure including a plurality of intermediate layers IL1, IL2, and IL3 for emitting different light from each other. For example, the intermediate layer IL may include a first intermediate layer IL1 for emitting light of a first color, a second intermediate layer IL2 for emitting light of a third color, and a third intermediate layer IL3 for emitting light of a second color. The first intermediate layer IL1, the second intermediate layer IL2, and the third intermediate layer IL3 may be sequentially stacked on one another.

A charge generation layer may be disposed between the first intermediate layer IL1 and the second intermediate layer IL2. In addition, a charge generation layer may be disposed between the second intermediate layer IL2 and the third intermediate layer IL3. The charge generation layer may include a negative charge generation layer and a positive charge generation layer.

The first intermediate layer IL1 may have a structure in which a first hole transporting layer, a first organic light emitting layer for emitting light of a first color, and a first electron transporting layer are sequentially stacked on one another. The second intermediate layer IL2 may have a structure in which a second hole transporting layer, a second organic light emitting layer for emitting light of a third color, and a second electron transporting layer are sequentially stacked on one another. The third intermediate layer IL3 may have a structure in which a third hole transporting layer, a third organic light emitting layer for emitting light of a second color, and a third electron transporting layer are sequentially stacked on one another.

The intermediate layer IL covers the first electrode AND at a opening of the pixel defining layer PDL, and covers the pixel defining layer PDL between the sub-pixels SP1, SP2, and SP3 that are disposed to be adjacent to each other. A portion of the intermediate layer IL may be disconnected. The portion of the intermediate layer IL that is disconnected may be, for example, a portion of the charge generation layer disposed between the first intermediate layer IL1 and the second intermediate layer IL2, and the intermediate layer IL disposed below the charge generation layer. In addition, the portion of the intermediate layer IL that is disconnected may be, for example, a portion of the charge generation layer disposed between the second intermediate layer IL2 and the third intermediate layer IL3, and the intermediate layer IL disposed below the charge generation layer. However, the portion of the intermediate layer IL that is disconnected is not limited to the above examples, and the intermediate layer IL may be disconnected in a portion of the layer disposed on the charge generation layer.

In an embodiment, during the process of manufacturing the display panel, the intermediate layer IL may be disconnected between the sub-pixels SP1, SP2, and SP3 that are adjacent to each other using the reference wiring. According to such embodiments, it may be possible to prevent or substantially prevent a leakage current between the sub-pixels SP1, SP2, and SP3 that are adjacent to each other, and prevent or substantially prevent color crosstalk. The color crosstalk refers to, for example, a phenomenon in which a red sub-pixel that is adjacent to a blue sub-pixel is unintentionally turned on while the blue sub-pixel emits light of a blue color. The color crosstalk may occur due to a leakage current, and may occur when the blue sub-pixel and the red sub-pixel that have a large difference in voltage for driving the pixels are adjacent to each other. For example, the leakage current may be a phenomenon in which a portion of the driving current is transmitted to the red sub-pixel through at least a portion of a conductive layer of the intermediate layer IL, while the driving current is supplied to the light emitting element LE of the blue sub-pixel to turn on the blue sub-pixel. When the leakage current occurs, the red sub-pixel may be unintentionally turned on while the blue sub-pixel is turned on.

The number of the intermediate layers IL1, IL2, and IL3 for emitting different colors of light from each other is not limited to that illustrated in FIG. 9. For example, the intermediate layer IL may include two intermediate layers. In this case, one of the two intermediate layers may be the same or substantially the same as the first intermediate layer IL1, and the other thereof may include a second hole transporting layer, a second organic light emitting layer, a third organic light emitting layer, and a second electron transporting layer. In this case, a charge generation layer for supplying electrons to one intermediate layer and for supplying holes to the other intermediate layer may be disposed between the two intermediate layers.

In addition, FIG. 9 illustrates that the first to third intermediate layers IL1, IL2, and IL3 are all disposed in each of the first light emitting area EA1, the second light emitting area EA2, and the third light emitting area EA3, but the present disclosure is not limited thereto. For example, the first intermediate layer IL1 may be disposed in the first light emitting area EA1, and may not be disposed in the second light emitting area EA2 and the third light emitting area EA3. In addition, the second intermediate layer IL2 may be disposed in the second light emitting area EA2, and may not be disposed in the first light emitting area EA1 and the third light emitting area EA3. In addition, the third intermediate layer IL3 may be disposed in the third light emitting area EA3, and may not be disposed in the first light emitting area EA1 and the second light emitting area EA2. In this case, first to third color filters CF1, CF2, and CF3 of the optical layer OPL described in more detail below may be omitted.

The second electrode CAT may be disposed on the third intermediate layer IL3. The second electrode CAT may be disposed on the third intermediate layer IL3 in each of a plurality of trenches. The second electrode CAT may be formed of a transparent conductive material (TCO), such as ITO or IZO, capable of transmitting light, or a semi-transmissive conductive material, such as magnesium (Mg), silver (Ag), or an alloy of magnesium (Mg) and silver (Ag). When the second electrode CAT is formed of the semi-transmissive conductive material, light emission efficiency may be increased in each of the first to third sub-pixels SP1, SP2, and SP3 by micro cavities.

The encapsulation layer TFE may be disposed on the light emitting element layer EML. The encapsulation layer TFE may include one or more inorganic films TFE1 and TFE3 to prevent or substantially prevent oxygen and/or moisture from permeating into the light emitting element layer EML. In addition, the encapsulation layer TFE may include at least one organic film TFE2 to protect the light emitting element layer EML from foreign substances, such as dust. For example, the encapsulation layer TFE may include a first encapsulation inorganic film TFE1, an encapsulation organic film TFE2, and a second encapsulation inorganic film TFE3.

The first encapsulation inorganic film TFE1 may be disposed on the second electrode CAT. The encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed as multiple layers in which one or more inorganic layers of a silicon nitride (SiNₓ) layer, a silicon oxynitride (SiON) layer, a silicon oxide (SiOₓ) layer, a titanium oxide (TiOₓ) layer, and an aluminum oxide (AlOₓ) layer are alternately stacked on one another. The encapsulation organic film TFE2 may be a monomer. As another example, the encapsulation organic film TFE2 may be an organic film including (e.g., made of) an acrylic resin, an epoxy resin, a phenolic resin, a polyamide resin, or a polyimide resin.

An adhesive layer ADL may be a layer for adhering the encapsulation layer TFE and the optical layer OPL to each other. The adhesive layer ADL may be a double-sided adhesive member. In addition, the adhesive layer ADL may be a transparent adhesive member, such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap with the first light emitting area EA1 of the first sub-pixel SP1. The first color filter CF1 may transmit light of a first color, or in other words, light in a blue wavelength band. The blue wavelength band may be approximately 370 nm to 460 nm. Therefore, the first color filter CF1 may transmit light of a first color from among the light emitted from the first light emitting area EA1.

The second color filter CF2 may overlap with the second light emitting area EA2 of the second sub-pixel SP2. The second color filter CF2 may transmit light of a second color, or in other words, light in a green wavelength band. The green wavelength band may be approximately 480 nm to 560 nm. Therefore, the second color filter CF2 may transmit light of a second color from among the light emitted from the second light emitting area EA2.

The third color filter CF3 may overlap with the third light emitting area EA3 of the third sub-pixel SP3. The third color filter CF3 may transmit light of a third color, or in other words, light in a red wavelength band. The red wavelength band may be approximately 600 nm to 750 nm. Therefore, the third color filter CF3 may transmit light of a third color from among the light emitted from the third light emitting area EA3.

Each of the plurality of lenses LNS may be disposed on a corresponding one of the first color filter CF1, the second color filter CF2, and the third color filter CF3. Each of the plurality of lenses LNS may be a structure for increasing a ratio of light directed to the front of the display device 10 (see FIG. 4). Each of the plurality of lenses LNS may have a cross-sectional shape that is convex in an upward direction.

The filling layer FIL may be disposed on the plurality of lenses LNS. The filling layer FIL may have a suitable refractive index (e.g., a predetermined refractive index), so that light travels in the third direction DR3 at an interface between the plurality of lenses LNS and the filling layer FIL. In addition, the filling layer FIL may be a planarization layer. The filling layer FIL may be an organic film including (e.g., made of) an acryl resin, an epoxy resin, a phenolic resin, a polyamide resin, or a polyimide resin.

The cover layer CVL may be disposed on the filling layer FIL. The cover layer CVL may be a glass substrate or a polymer resin. When the cover layer CVL is a glass substrate, the cover layer CVL may be attached onto the filling layer FIL. In this case, the filling layer FIL may serve to adhere to the cover layer CVL. When the cover layer CVL is a glass substrate, the cover layer CVL may serve as an encapsulation substrate. When the cover layer CVL is a polymer resin, the cover layer CVL may be directly applied on the filling layer FIL.

The polarizing plate may be disposed on one surface of the cover layer CVL. The polarizing plate may be a structure for preventing or substantially preventing a deterioration in visibility due to a reflection of external light. The polarizing plate may include a linear polarizing plate and a phase retardation film. For example, the phase retardation film may be a λ/4 (quarter-wave) plate, but the present disclosure is not limited thereto. However, when the deterioration in visibility due to the reflection of external light is sufficiently improved by the first to third color filters CF1, CF2, and CF3, the polarizing plate may be omitted.

FIG. 10 is a plan view illustrating an arrangement of the first electrodes of the sub-pixels according to an embodiment.

Referring to FIG. 10, the first electrode AND of each of the plurality of sub-pixels SP1, SP2, and SP3 (see FIG. 9) may have a hexagonal shape in a plan view.

For example, each of the first electrodes AND may have a hexagonal shape, and be disposed at suitable intervals along the first direction DR1.

The display panel 410 may include the reference wiring 1010 including the first reference wiring 1011 and the second reference wiring 1012. The first reference wiring 1011 may extend in the first direction DR1 while crossing between the first electrodes AND, and may have a first length in the display area DAA. The second reference wiring 1012 may have a second length in the display area DAA.

The first reference wiring 1011 may be disposed to cross between the first electrodes AND of a 2n-1-th row R_2n-1 and the first electrodes AND of a 2n-th row R_2n in the first direction DR1, where n is a natural number greater than 0. For example, the first reference wiring 1011 may be an odd-numbered wiring from among the reference wirings 1010.

The second reference wiring 1012 may be disposed to cross between the first electrodes AND of the 2n-th row R_2n and the first electrodes AND of a 2n+1-th row R_2n+1 in the first direction DR1. For example, the second reference wiring 1012 may be an even-numbered wiring from among the reference wirings 1010.

According to an embodiment, each of the first electrodes AND has a hexagonal shape, and may include a protruding portion AND_P that protrudes in a direction of the first reference wiring 1011. The protruding portion AND_P of the first electrode AND may be an area in which a contact hole for connection to the light emitting element backplane EBP (see FIG. 9) is disposed.

Because the first reference wiring 1011 may be disposed to cross between the first electrodes AND of the 2n-1-th row R_2n-1 and the first electrodes AND of the 2n-th row R_2n in the first direction DR1, the first electrodes AND of the odd-numbered rows R_2n-1 and R_2n+1 may have the protruding portions AND_P formed in the second direction DR2 perpendicular to or substantially perpendicular to the first direction DR1, and the first electrodes AND of the even-numbered row R_2n may have the protruding portions AND_P formed in the fourth direction DR4 opposite to the second direction DR2. Because the first reference wiring 1011 extends in the first direction DR1 while crossing between the protruding portions AND_P, a length thereof may be longer than that of the second reference wiring 1012.

According to an embodiment, a metal pattern wiring 1040 connecting the reference wiring 1010 and the power pad 1030 to each other is disposed in the non-display area NDA. The metal pattern wiring 1040 may serve to supply a Joule heating voltage V_{Heat} or a Joule heating current I_{Heat} applied to the power pad 1030 to the reference wiring 1010. The metal pattern wiring 1040 may include a first metal pattern wiring (e.g., a third wiring) 1041 connected to the first reference wiring 1011, and a second metal pattern wiring (e.g., a fourth wiring) 1042 connected to the second reference wiring 1012.

The first metal pattern wiring 1041 may extend to have a straight or substantially straight line in a plan view.

Because at least a portion of the second metal pattern wiring 1042 may have a zigzag shape in a plan view, a length of the second metal pattern wiring 1042 may be longer than that of the first metal pattern wiring 1041. For example, the first metal pattern wiring 1041 may have a third length, and the second metal pattern wiring 1042 may have a fourth length that is longer than the third length. Because at least a portion of the second metal pattern wiring 1042 may be disposed in a zigzag shape in a plan view, the second metal pattern wiring 1042 may have the fourth length that is longer than the third length.

However, the shape of the portion of the second metal pattern wiring 1042 that has the zigzag shape in a plan view is provided as an example, and the shape of the second metal pattern wiring 1042 may be variously modified as needed or desired. For example, at least a portion of the second metal pattern wiring 1042 may be disposed to have a specific pattern in a plan view, and the specific pattern may be variously modified into various suitable shapes as needed or desired. In other words, the zigzag shape of the second metal pattern wiring 1042 is provided only as an example of the specific pattern, and the present disclosure is not limited thereto.

A first total length obtained by adding the first length of the first reference wiring 1011 and the third length of the first metal pattern wiring 1041 to each other may be equal to or substantially equal to a second total length obtained by adding the second length of the second reference wiring 1012 and the fourth length of the second metal pattern wiring 1042 to each other. Accordingly, the resistance deviation or variation between the first and second reference wirings 1011 and 1012 that may occur in the display area DAA may be compensated for.

According to an embodiment, one end of the reference wiring 1010 may be connected to the power pad 1030 through the metal pattern wiring 1040, and another end (e.g., an opposite end) of the reference wiring 1010 may be connected to a ground pad 1050 through a ground wiring 1060. For example, the power pad 1030 may be disposed at one end of the non-display area NDA, and the ground pad 1050 may be disposed at another end of the non-display area NDA. The ground wiring 1060, like the metal pattern wiring 1040, may be disposed in a zigzag shape to compensate for a resistance deviation or variation between the first and second reference wirings 1011 and 1012. In more detail, the power pad 1030 may be disposed at one end of the non-display area NDA that is adjacent to one end of the reference wiring 1010. The other end of the non-display area NDA adjacent to the other end of the reference wiring 1010 may include a first ground wiring 1061 and a second ground wiring 1062 that connect the ground pad 1050 and the reference wiring 1010 to each other.

The first ground wiring 1061 may be connected to the first reference wiring 1011, and may extend in a straight or substantially straight line. The second ground wiring 1062 may be connected to the second reference wiring 1012, and may extend in a zigzag shape. Unlike the first ground wiring 1061, because the second ground wiring 1062 may be disposed in the zigzag shape, a resistance thereof may be relatively higher. The resistance deviation or variation between the first ground wiring 1061 and the second ground wiring 1062 may be designed to compensate for the resistance deviation or variation between the first reference wiring 1011 and the second reference wiring 1012.

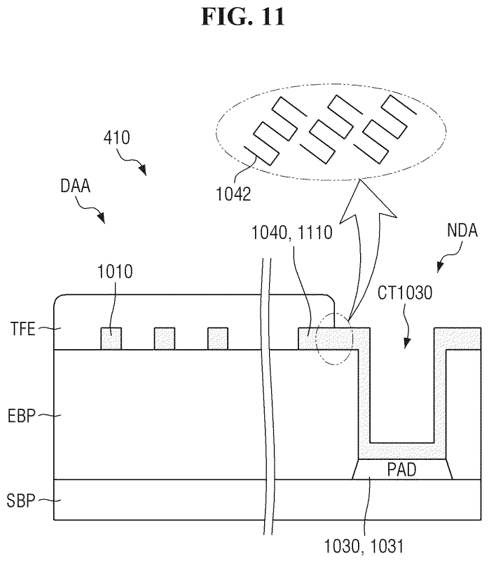

FIG. 11 is a cross-sectional view schematically illustrating a connection between a reference wiring and a pad portion of the display panel according to an embodiment.

Referring to FIG. 11, the reference wiring 1010 disposed in the display area DAA may be electrically connected to the power pad 1030 through the metal pattern wiring 1040 and a fan-out wiring 1110 disposed in the non-display area NDA. As in the illustrated example, the metal pattern wiring 1040 and the fan-out wiring 1110 may be disposed at (e.g., in or on) the same layer as that of the reference wiring 1010, and a distal end of the fan-out wiring 1110 may be connected to the pad electrode 1031 of the power pad 1030 through a contact hole CT1030 penetrating through a portion of the display panel 410. For example, the pad electrode 1031 of the power pad 1030 may be disposed at (e.g., in or on) the same layer as that of one of the first to eighth metal layers ML1 to ML8 of the light emitting element backplane EBP (see FIG. 9), but the present disclosure is not limited thereto.

The reference symbol EBP shown in FIG. 11 may represent the light emitting element backplane EBP described above with reference to FIG. 9.

The reference symbol TFE shown in FIG. 11 may represent the encapsulation layer TFE described above with reference to FIG. 9.

FIG. 12 is a layout view illustrating a pad portion and fan-out lines (also referred to as fan-out wirings) disposed in the non-display area of the display panel according to an embodiment. FIG. 13 is an enlarged view illustrating more details of wirings between the power pad and the reference wiring illustrated in FIG. 12.

Referring to FIGS. 12 and 13, a plurality of pads may be disposed on the outside of the display area DAA. The plurality of pads may include a power pad 1030, a common voltage pad 1210 connected to the second electrode CAT (see FIG. 9), and a ground pad 1050. In some embodiments, the pad portion may further include a plurality of pads to which signals and voltages for driving the display panel 410 (see FIG. 4) are applied, in addition to the power pad 1030, the common voltage pad 1210, and the ground pad 1050.

According to an embodiment, a metal pattern wiring 1040 and a fan-out wiring 1110 connecting the reference wiring 1010 and the power pad 1030 may be disposed in the non-display area NDA of the display panel 410. For example, the joule heating voltage V_{Heat} (see FIG. 10) input to the power pad 1030 may be supplied to the reference wiring 1010 disposed in the display area DAA via the fan-out wiring 1110 and the metal pattern wiring 1040 disposed in the non-display area NDA.

In FIG. 13, a first area 1301 in which the metal pattern wiring 1040 is disposed, and a second area 1302 in which the fan-out wiring 1110 is disposed are shown. The metal pattern wiring 1040 disposed in the first area 1301 may include the first metal pattern wiring 1041 disposed in the straight or substantially straight line and having the third length, and the second metal pattern wiring 1042 disposed in the zigzag shape and having the fourth length, as described above with reference to FIG. 10.

The fan-out wirings 1110 disposed in the second area 1302 may be disposed to converge in a direction of the power pad 1030, unlike the metal pattern wiring 1040 disposed to extend in or substantially in the first direction DR1. For example, in order to connect to the metal pattern wirings 1040 disposed at the suitable intervals, the fan-out wirings 1110 connected from one power pad 1030 may extend in diagonal directions at different angles, and their lengths may be designed to be differential.

According to an embodiment, in order to compensate for the resistance deviation or variation due to the length deviation or variation of the fan-out wiring 1110 having lengths that are differentially increased or decreased between the power pad 1030 and the metal pattern wiring 1040, the fan-out wiring 1110 may include a length deviation compensation portion 1111. For example, the plurality of fan-out wirings 1110 according to an embodiment may all have the same or substantially the same length as each other by including the length deviation compensation portion 1111. The length deviation compensation portion 1111 of each fan-out wiring 1110 may include a differentially designed zigzag wiring of a suitable length (e.g., a specified or predetermined length).

However, at least a portion of the length deviation compensation portion 1111 that has a zigzag shape in a plan view is provided only as an example, and the shape of the length deviation compensation portion 1111 may be variously modified as needed or desired. For example, at least a portion of the length deviation compensation portion 1111 may be disposed to have a specific pattern in a plan view, and the specific pattern may be variously modified into various suitable shapes. In other words, the zigzag shape of the length deviation compensation portion 1111 is provided only as an example of the specific pattern, and the present disclosure is not limited thereto.

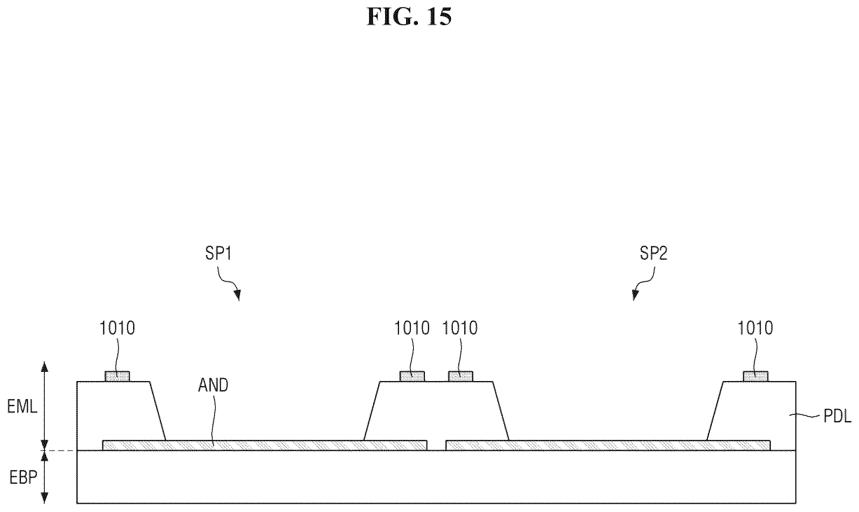

FIG. 14 is a flowchart illustrating a method of manufacturing a display device according to an embodiment. FIGS. 15 through 18 are cross-sectional views illustrating various processes of a method of manufacturing a display device.

Hereinafter, a method of manufacturing the display panel 410 (see FIG. 4) according to an embodiment will be described in more detail with reference to FIGS. 14 through 18. The following describes only a portion of the various processes of manufacturing the display panel 410, and additional processes for forming one or more of the components described above may be performed before or after each process described in more detail below. In addition, various suitable processes of manufacturing the display panel 410 as known by those having ordinary skill in the art may be additionally performed before or after each process described in more detail below.

Referring to FIG. 14, in block 1410, a driving element layer may be formed on a substrate SSUB. For example, the substrate SSUB may be the semiconductor substrate SSUB described above with reference to FIG. 9. The driving element layer may be a remaining portion of the semiconductor backplane SBP described above with reference to FIG. 9 excluding the semiconductor substrate SSUB.

In block 1420, a wiring layer EBP may be formed on the driving element layer. For example, the wiring layer EBP may be the light emitting element backplane EBP described above with reference to FIG. 9. The wiring layer EBP may include the first to eighth metal layers ML1 to ML8, the reflective metal layers RL1 to RL4, the plurality of vias VA1 to VA10, and the step layer STPL described above with reference to FIG. 9.

In block 1430, a first electrode AND of each sub-pixel SP1, SP2, and SP3 and a pixel defining layer PDL partitioning the sub-pixels SP1, SP2, and SP3 may be formed on the wiring layer EBP (see FIG. 9). A portion of the first electrode AND may be exposed through an opening in the pixel defining layer PDL.

Referring to FIGS. 14 and 15, in block 1440, a reference wiring 1010 may be formed on the pixel defining layer PDL between the sub-pixels SP1, SP2, and SP3 disposed to be adjacent to each other. As described above, the reference wiring 1010 may include the first reference wiring 1011 and the second reference wiring 1012 (see FIG. 10).

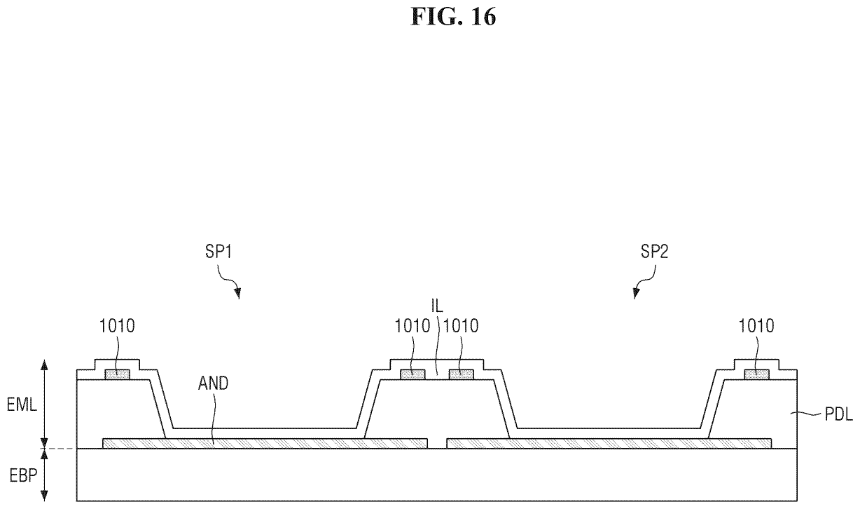

Referring to FIGS. 14 and 16, in block 1450, the intermediate layer IL may be deposited. The intermediate layer IL may be deposited on the opening of the pixel defining layer PDL using an open mask, as well as on an upper portion of the pixel defining layer PDL disposed between the sub-pixels SP1, SP2, and SP3 that are adjacent to each other. Accordingly, the intermediate layer IL may cover a portion of the first electrode AND at the opening of the pixel defining layer PDL, and may also cover the reference wiring 1010 disposed on the pixel defining layer PDL.

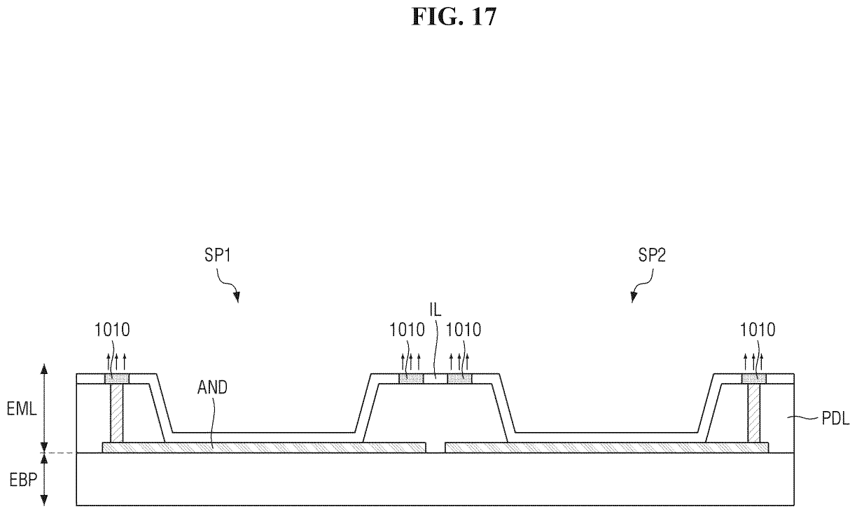

Referring to FIGS. 14 and 17, in block 1460, at least a portion of the intermediate layer IL disposed between the sub-pixels SP1, SP2, and SP3 that are adjacent to each other may be removed using the reference wiring 1010. For example, a Joule heating voltage V_{Heat} (see FIG. 10) may be applied to the power pad 1030, and the applied Joule heating voltage V_{Heat} may be transmitted to the reference wiring 1010 via the fan-out wiring 1110 and the metal pattern wiring 1040 (see FIG. 12). The reference wiring 1010 may be heated to a high temperature of about 400° C. or higher by the input Joule heating voltage V_{Heat}. All or at least a portion of the intermediate layer IL deposited on the reference wiring 1010 may be removed due to the high temperature of the reference wiring 1010.

The portion of the intermediate layer IL that is disconnected may be, for example, a portion of the charge generation layer disposed between the first intermediate layer IL1 and the second intermediate layer IL2 (see FIG. 9), and the intermediate layer IL disposed below the charge generation layer. In addition, the portion of the intermediate layer IL that is disconnected may be, for example, a portion of the charge generation layer disposed between the second intermediate layer IL2 and the third intermediate layer IL3 (see FIG. 9), and the intermediate layer IL disposed below the charge generation layer. However, the portion of the intermediate layer IL that is disconnected is not limited to the above examples, and the intermediate layer IL may be disconnected in a portion of the layer disposed on the charge generation layer.

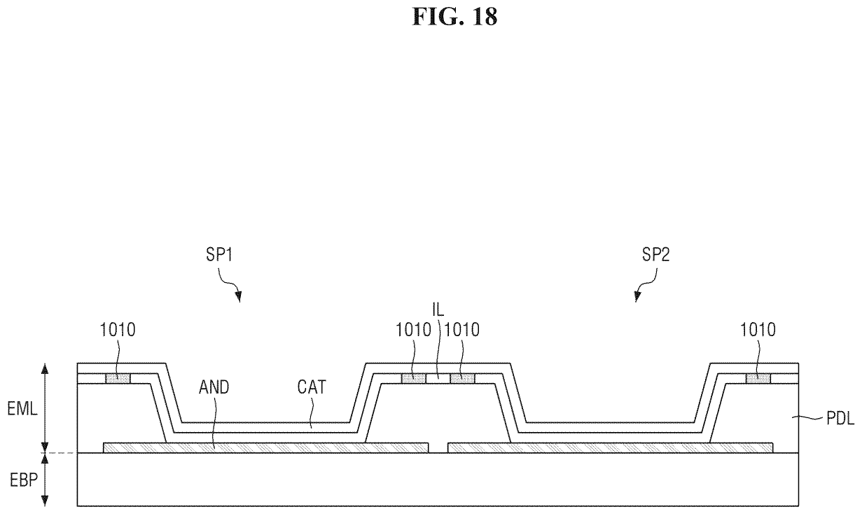

Referring to FIGS. 14 and 18, in block 1470, a second electrode CAT may be deposited. For example, the second electrode CAT may be deposited on the opening of the pixel defining layer PDL using an open mask, as well as on an upper portion of the pixel defining layer PDL disposed between the sub-pixels SP1, SP2, and SP3 that are adjacent to each other. Accordingly, the second electrode CAT may cover the intermediate layer IL at each opening of the pixel defining layer PDL, and may cover the intermediate layer IL and the reference wiring 1010 disposed on the pixel defining layer PDL.

According to one or more embodiments of the present disclosure, in the display device and the mobile electronic device including the same, a leakage current and a color crosstalk may be prevented or substantially prevented by disconnecting at least a portion of the intermediate layer disposed between the pixel electrode and the common electrode between the adjacent pixels using the reference wiring.

According to one or more embodiments of the present disclosure, in the display device and the mobile electronic device including the same, the width and the height of the disconnection portion of the intermediate layer where the intermediate layer is disconnected may be uniformalized, and product defects due to the process deviation or variation of the disconnection portion may be reduced, by compensating for a resistance deviation or variation due to the length deviation or variation of the reference wiring.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
a driving element layer on the substrate; and
a light emitting element layer on the driving element layer, the light emitting element layer comprising:
a pixel defining layer partitioning a plurality of sub-pixels;
a first electrode of a sub-pixel from among the plurality of sub-pixels, the first electrode being located in an opening of the pixel defining layer;
wirings comprising:
a first wiring extending in a first direction while crossing between the first electrodes on the pixel defining layer, and having a first length in a display area; and
a second wiring having a second length shorter than the first length in the display area;
an intermediate layer covering the first electrode at the opening and covering the pixel defining layer, a portion of the intermediate layer being disconnected in an upper portion of the wirings;
a second electrode covering the intermediate layer in the opening, and continuously covering the intermediate layer and the wirings between sub-pixels that are adjacent to each other from among the plurality of sub-pixels; and
pattern wirings connected to the wirings in a non-display area and comprising a third wiring and a fourth wiring,
wherein the third wiring is connected to the first wiring and has a third length, and
wherein the fourth wiring is connected to the second wiring and has a fourth length longer than the third length.

2. The display device of claim 1, wherein the fourth wiring has a zigzag shape to have the fourth length longer than the third length.

3. The display device of claim 2, wherein a first total length obtained by adding the first length of the first wiring and the third length of the third wiring to each other is equal to a second total length obtained by adding the second length of the second wiring and the fourth length of the fourth wiring to each other.

4. The display device of claim 3, wherein the first wiring is an odd-numbered wiring of the wirings, and
wherein the second wiring is an even-numbered wiring of the wirings.

5. The display device of claim 1, wherein a power pad is located at one end of the non-display area adjacent to one end of the wirings,
wherein another end of the non-display area adjacent to another end of the wirings comprises a first ground wiring and a second ground wiring connecting a ground pad and the wirings to each other,
wherein the first ground wiring is connected to the first wiring and extends in a straight line, and
wherein the second ground wiring is connected to the second wiring and has a zigzag shape.

6. The display device of claim 5, wherein the ground pad is located at the other end of the non-display area.

7. The display device of claim 1, wherein the first electrode has a hexagonal shape in a plan view, and comprises a protruding portion protruding in a direction of the first wiring.

8. The display device of claim 1, wherein the plurality of sub-pixels comprises:
a first light emitting area of a first sub-pixel;
a second light emitting area of a second sub-pixel; and
a third light emitting area of a third sub-pixel,
wherein the first light emitting area and the second light emitting area are alternately located along the first direction in odd-numbered rows from among the plurality of sub-pixels,
wherein the third light emitting area is located at intervals along the first direction in even-numbered rows from among the plurality of sub-pixels, and
wherein a length of the third light emitting area in the first direction is greater than a sum of a length of the first light emitting area in the first direction and a length of the second light emitting area in the first direction.

9. The display device of claim 8, wherein the first wiring comprises:
a first portion between the first light emitting area and the third light emitting area;
a second portion extending from the first portion, and located between the first light emitting area and the second light emitting area; and
a third portion extending from the second portion, and located between the second light emitting area and the third light emitting area, and
wherein the second wiring comprises:
a fourth portion between the third light emitting area and the first and second light emitting areas; and
a fifth portion between the two third light emitting areas adjacent to each other.

10. The display device of claim 1, further comprising a plurality of fan-out wirings connecting between the pattern wirings and a power pad,
wherein the plurality of fan-out wirings all have the same length as each other by including a length deviation compensation portion, and
wherein the length deviation compensation portion of each of the fan-out wirings comprises a zigzag wiring of a different length from those of others of the fan-out wirings.

11. A mobile electronic device comprising:
a display panel comprising a light emitting element layer,
wherein the light emitting element layer comprises:
a pixel defining layer partitioning a plurality of sub-pixels;
a first electrode of a sub-pixel from among the plurality of sub-pixels, the first electrode being located in an opening of the pixel defining layer;
wirings comprising:
a first wiring extending in a first direction while crossing between the first electrodes on the pixel defining layer, and having a first length in a display area; and
a second wiring having a second length shorter than the first length in the display area;
an intermediate layer covering the first electrode at the opening and covering the pixel defining layer, a portion of the intermediate layer being disconnected in an upper portion of the wirings;
a second electrode covering the intermediate layer in the opening, and continuously covering the intermediate layer and the wirings between sub-pixels that are disposed to be adjacent to each other from among the plurality of sub-pixels; and
pattern wirings connected to the wirings in a non-display area and comprising a third wiring and a fourth wiring,
wherein the third wiring is connected to the first wiring and has a third length, and
wherein the fourth wiring is connected to the second wiring, and has a fourth length longer than the third length.

12. The mobile electronic device of claim 11, wherein the fourth wiring has a zigzag shape to have the fourth length longer than the third length.

13. The mobile electronic device of claim 12, wherein a first total length obtained by adding the first length of the first wiring and the third length of the third wiring to each other is equal to a second total length obtained by adding the second length of the second wiring and the fourth length of the fourth wiring to each other.

14. The mobile electronic device of claim 13, wherein the first wiring is an odd-numbered wiring of the wirings, and
wherein the second wiring is an even-numbered wiring of the wirings.

15. The mobile electronic device of claim 11, wherein a power pad is located at one end of the non-display area adjacent to one end of the wirings,
wherein another end of the non-display area adjacent to another end of the wirings comprises a first ground wiring and a second ground wiring connecting a ground pad and the wirings to each other,
wherein the first ground wiring is connected to the first wiring and extends in a straight line, and
wherein the second ground wiring is connected to the second wiring and has a zigzag shape.

16. The mobile electronic device of claim 15, wherein the ground pad is located at the other end of the non-display area.

17. The mobile electronic device of claim 11, wherein the first electrode has a hexagonal shape in a plan view, and comprises a protruding portion protruding in a direction of the first wiring.

18. The mobile electronic device of claim 11, wherein the plurality of sub-pixels comprises:
a first light emitting area of a first sub-pixel;
a second light emitting area of a second sub-pixel; and
a third light emitting area of a third sub-pixel,
wherein the first light emitting area and the second light emitting area are alternately located along the first direction in odd-numbered rows from among the plurality of sub-pixels,
wherein the third light emitting area is located at intervals along the first direction in even-numbered rows from among the plurality of sub-pixels, and
wherein a length of the third light emitting area in the first direction is greater than a sum of a length of the first light emitting area in the first direction and a length of the second light emitting area in the first direction.

19. The mobile electronic device of claim 18, wherein the first wiring comprises:
a first portion between the first light emitting area and the third light emitting area;
a second portion extending from the first portion, and located between the first light emitting area and the second light emitting area; and
a third portion extending from the second portion, and located between the second light emitting area and the third light emitting area, and
wherein the second wiring comprises:
a fourth portion between the third light emitting area and the first and second light emitting areas; and
a fifth portion between the two third light emitting areas adjacent to each other.

20. The mobile electronic device of claim 11, further comprising a plurality of fan-out wirings connecting between the pattern wirings and a power pad,
wherein the plurality of fan-out wirings all have the same length as each other by including a length deviation compensation portion, and
wherein the length deviation compensation portion of each of the fan-out wirings comprises a zigzag wiring of a different length from those of others of the fan-out wirings.
